(19) United States
(12) Patent Application Publication
(10) Pub. No.: US 2025/0081764 A1
(43) Pub. Date: Mar. 6, 2025

(54) Display Panel and Display Apparatus

(71) Applicant: BOE Technology Group Co., Ltd., Beijing (CN)

(72) Inventors: Ming YANG, Beijing (CN); Xuan FENG, Beijing (CN); Liwei LIU, Beijing (CN); Zhuo LI, Beijing (CN); Hui ZHANG, Beijing (CN); Seungwoo HAN, Beijing (CN); Yanliu SUN, Beijing (CN)

(21) Appl. No.: 18/279,217

(22) PCT Filed: Nov. 28, 2022
(86) PCT No.: PCT/CN2022/134696

§ 371 Date: Aug. 29, 2023

(51) Int. Cl. H10K 59/131

(52) U.S. Cl. CPC H10K 59/131

(57) ABSTRACT

A display panel and a display apparatus. The display panel includes a substrate, and pixel islands (Pi) arranged in an array on the substrate, and at least one pixel island (Pi) includes a plurality of pixel drive circuits (10) and a plurality of light emitting devices, wherein a light emitting device includes a first electrode (20), and at least one pixel drive circuit (10) is electrically connected with at least one light emitting device; first electrodes (20) of a plurality of light emitting devices on a same pixel island are arranged in a first direction, and an orthographic projection of a first electrode (20) of at least one light emitting device on the substrate is at least partially overlapped with an orthographic projection of at least two pixel drive circuits (10) on the substrate.

### CROSS-REFERENCE TO RELATED APPLICATION

The present application is a U.S. National Phase Entry of International Application No. PCT/CN2022/134696 having an international filing date of Nov. 28, 2022, the content of which is hereby incorporated by reference.

### TECHNICAL FIELD

The present disclosure relates to, but is not limited to, the field of display technologies, and more particularly, to a display panel and a display apparatus.

### BACKGROUND

An Organic Light Emitting Diode (OLED for short) and a Quantum dot Light Emitting Diode (QLED for short) are active light emitting display devices, and have advantages such as self-luminescence, a wide viewing angle, a high contrast ratio, low power consumption, an extremely high response speed, lightness and thinness, flexibility, and a low cost. With continuous development of display technologies, a flexible display apparatus (Flexible Display) in which an OLED or a QLED is used as a light emitting device and signal control is performed using a Thin Film Transistor (TFT for short) has become a mainstream product in the field of display at present.

### SUMMARY

The following is a summary of the subject matter described in detail in the present application. The summary is not intended to limit the protection scope of claims.

In a first aspect, the present disclosure provides a display panel, including a substrate and pixel islands arranged in an array on the substrate. At least one pixel island includes a plurality of pixel drive circuits and a plurality of light emitting devices, a light emitting device includes a first electrode, and at least one pixel drive circuit is electrically connected with a first electrode of the at least one light emitting device.

First electrodes of a plurality of light emitting devices in a same pixel island are arranged along a first direction, and an orthographic projection of a first electrode of at least one light emitting device on the substrate is at least partially overlapped with an orthographic projection of at least two pixel drive circuits on the substrate.

In an exemplary implementation, at least one pixel island includes K light emitting devices, and a plurality of pixel drive circuits included in the at least one pixel island are arranged in an arrangement of M rows and N columns, wherein the first direction is a column direction, the second direction intersecting with the first direction is a row direction, and M, N are positive integers greater than or equal to 1.

In an exemplary implementation, when M>1, a pixel drive circuit at an i-th row and a j-th column is electrically connected with a first electrode of the light emitting device at an (N*(i−1)+j)th row, i and j are positive integers, wherein 1≤i≤M, 1≤j≤N, and M*N=K.

In an exemplary implementation, when M is equal to 1, a pixel drive circuit at a j-th column is electrically connected to a first electrode of a light emitting device of at a (1+K* (j−1)/N)-th row to a first electrode of a light emitting device at a (K*j/N)-th row, respectively, wherein j is a positive integer, and 1≤j<N.

In an exemplary implementation, adjacent column pixel drive circuits located in the same row are mirror symmetrical with respect to a virtual straight line extending along the first direction.

In an exemplary implementation, at least one pixel island further includes a plurality of light emitting control signal lines, and the pixel drive circuit includes a drive transistor and a light emitting control transistor.

A control electrode of the light emitting control transistor is electrically connected to a light emitting control signal line, a first electrode of the light emitting control transistor is electrically connected to the drive transistor, and a second electrode of the light emitting control transistor is electrically connected to a first electrode of a light emitting device to which the pixel drive circuit is electrically connected.

In an exemplary implementation, at least one pixel island further includes a plurality of reset signal lines, a plurality of scan signal lines, a plurality of initial signal lines, a plurality of first power supply lines and a plurality of data signal lines, and the pixel drive circuit further includes a node reset transistor, a compensation transistor, a writing transistor, and a control transistor.

For any pixel drive circuit, a control electrode of a node reset transistor is electrically connected to a reset signal line, a first electrode of the node reset transistor is electrically connected to an initial signal line, and a second electrode of the node reset transistor is electrically connected to the first node; a control electrode of a compensation transistor is electrically connected to a scan signal line, a first electrode of the compensation transistor is electrically connected to the first node, and a second electrode of the compensation transistor is electrically connected to the third node; a control electrode of a drive transistor is electrically connected to the first node, a first electrode of the drive transistor is electrically connected to the second node, and a second electrode of the drive transistor is electrically connected to the third node; a control electrode of the writing transistor is electrically connected to the scan signal line, a first electrode of the writing transistor is electrically connected to a data signal line, and a second electrode of the writing transistor is electrically connected to the second node; a control electrode of the light emitting transistor is electrically connected to a light emitting control signal line, a first electrode of the light emitting transistor is electrically connected to a first power supply line, and a second electrode of the light emitting transistor is electrically connected to the second node; and a first electrode of the sixth transistor is electrically connected to the third node.

In an exemplary implementation, at least one pixel island further includes K/N light emitting signal lines, and the pixel drive circuit includes: a drive transistor, and K/N light emitting control transistors which are arranged along the first direction.

A control electrode of a k-th light emitting control transistor is electrically connected with a k-th light emitting signal line, a first electrode of the k-th light emitting control transistor is electrically connected with the drive transistor, and a second electrode of the k-th light emitting control transistor is electrically connected with a k-th light emitting device to which the pixel drive circuit is electrically connected, wherein k is a positive integer and 1≤k≤K/N.

In an exemplary implementation, at least one pixel island further includes one reset signal line, one scan signal line, one light emitting control signal line, one initial signal line, at least one first power supply line and a plurality of data signal lines, and the pixel drive circuit further includes a node reset transistor, a compensation transistor, a writing transistor and a control transistor.

For any pixel drive circuit, a control electrode of a node reset transistor is electrically connected to a reset signal line, a first electrode of the node reset transistor is electrically connected to an initial signal line, and a second electrode of the node reset transistor is electrically connected to the first node; a control electrode of a compensation transistor is electrically connected to a scan signal line, a first electrode of the compensation transistor is electrically connected to the first node, and a second electrode of the compensation transistor is electrically connected to the third node; a control electrode of a drive transistor is electrically connected to the first node, a first electrode of the drive transistor is electrically connected to the second node, and a second electrode of the drive transistor is electrically connected to the third node; a control electrode of the writing transistor is electrically connected to the scan signal line, a first electrode of the writing transistor is electrically connected to a data signal line, and a second electrode of the writing transistor is electrically connected to the second node; a control electrode of the light emitting transistor is electrically connected to a light emitting control signal line, a first electrode of the light emitting transistor is electrically connected to a first power supply line, and a second electrode of the light emitting transistor is electrically connected to the second node; and a first electrode of a k-th light emitting control transistor is electrically connected to the third node.

In an exemplary implementation, when the signal of one light emitting signal line is an effective level signal, the signals of other light emitting signal lines are all ineffective level signals except that the light emitting signal line whose signal is an effective level.

Time for which a signal of any one light emitting signal line is an effective level signal is partially overlapped with time for which a signal of the light emitting control signal line is an effective level signal.

In an exemplary implementation, an orthographic projection of a second electrode of a light emitting control transistor of any one pixel drive circuit on the substrate is at least partially overlapped with an orthographic projection of the first electrode of the light emitting device to which the light emitting control transistor is electrically connected on the substrate.

In an exemplary implementation, an orthographic projection of a second electrode of a light emitting control transistor of any one pixel drive circuit on a substrate is not overlapped with an orthographic projection of a first electrode of the light emitting device to which the light emitting control transistor is electrically connected on the substrate.

In an exemplary implementation, the at least one pixel island further includes a plurality of signal connection lines, and a signal connection line is arranged in a film layer between a film layer where the second electrode of the light emitting control transistor is located and a film layer where the first electrode is located.

The signal connection line is electrically connected to the second electrode of the light emitting control transistor of the pixel drive circuit and the first electrode of the light emitting device to which the light emitting control transistor is electrically connected.

The signal connection line is a metal conductive line or metal oxide conductive line.

In an exemplary implementation, the pixel drive circuit includes a first pixel drive circuit and a second pixel drive circuit; an orthographic projection of a second electrode of a light emitting control transistor of the first pixel drive circuit on the substrate is not overlapped with an orthographic projection of a first electrode of a light emitting device, to which the first pixel drive circuit is electrically connected, on the substrate, and an orthographic projection of a second electrode of a light emitting control transistor of the second pixel drive circuit on the substrate is at least partially overlapped with an orthographic projection of a first electrode of a light emitting device, to which a second pixel drive circuit is electrically connected, on the substrate.

In an exemplary implementation, at least one pixel island further includes a plurality of first signal connection lines, and a first signal connection line is arranged in a film layer between a film layer where the second electrode of the light emitting control transistor is located and a film layer where the first electrode is located.

The first signal connection line is electrically connected with the second electrode of the light emitting control transistor of the first pixel drive circuit and the first electrode of the light emitting device to which the first pixel drive circuit is electrically connected.

The first signal connection line is a metal conductive line or metal oxide conductive line.

In an exemplary implementation, at least one pixel island further includes a plurality of second signal connection lines, and a second signal connection line is arranged in a same layer as the first signal connection line.

The second signal connection line is electrically connected to the second electrode of the light emitting control transistor of the second pixel drive circuit and the first electrode of the light emitting device to which the second pixel drive circuit is electrically connected.

The second signal connection line is a metal conductive line or metal oxide conductive line.

In an exemplary implementation, the K/N light emitting control transistors of the pixel drive circuit include a first type of transistors and a second type of transistors, wherein an orthographic projection of a second electrode of a first type of transistor on the substrate is not overlapped with an orthographic projection of a first electrode of a light emitting device to which the first type of transistor is electrically connected on the substrate, and an orthographic projection of a second electrode of a second type of transistor on the substrate is at least partially overlapped with an orthographic projection of a first electrode of a light emitting device to which the second type of transistor are electrically connected on the substrate.

In an exemplary implementation, at least one pixel island further includes a plurality of third signal connection lines, and a third signal connection line is arranged in a film layer between a film layer where a second electrode of a first type of transistor is located and a film layer where a first electrode is located.

The third signal connection line is electrically connected to the second electrode of the first type of transistor and the first electrode of the light emitting device to which the first type of transistor is electrically connected.

The third signal connection line is a metal conductive line or metal oxide conductive line.

In an exemplary implementation, at least one pixel island further includes a plurality of fourth signal connection lines, and a fourth signal connection line is arranged in a same layer as the third signal connection line.

The fourth signal connection line is electrically connected to a second electrode of a second type of transistor and a first electrode of a light emitting device to which a second type of transistors is electrically connected.

The fourth signal connection line is a metal conductive line or metal oxide conductive line.

In an exemplary implementation, the pixel island includes a first color pixel island, a second color pixel island and a third color pixel island, and adjacent first color pixel island, second color pixel island and third color pixel island, that are three adjacent pixel islands, form one pixel; and a first color pixel island, a second color pixel island and a third color pixel island located within a same pixel are arranged along a second direction, wherein the first direction intersects with the second direction.

In an exemplary implementation, a shape of the first electrode of the light emitting device is a parallelogram; and an extension direction of short sides of the parallelogram is parallel to the first direction.

In second aspect, the present disclosure further provides a display apparatus, including the display panel described above.

Other aspects may be understood upon reading and understanding the drawings and detailed description.

### BRIEF DESCRIPTION OF DRAWINGS

Accompanying drawings are used for providing understanding of technical solutions of the present disclosure, and form a part of the specification. They are used for explaining the technical solutions of the present disclosure together with embodiments of the present disclosure, but do not form a limitation on the technical solutions of the present disclosure.

FIG. 1 is a schematic diagram of a structure of a display panel provided by an embodiment of the present disclosure.

FIG. 2A is a first schematic diagram of a structure of two pixel islands in the display panel provided by an embodiment of the present disclosure.

FIG. 2B is a second schematic diagram of a structure of two pixel islands in the display panel provided by an embodiment of the present disclosure.

FIG. 3 is a schematic diagram of a structure of two pixel islands in a display panel.

FIG. 4A is a first equivalent circuit diagram of a pixel drive circuit of the display panel provided in FIG. 2A.

FIG. 4B is a second equivalent circuit diagram of the pixel drive circuit of the display panel provided in FIG. 2A.

FIG. 5 is a working timing diagram of the pixel drive circuits provided in FIG. 4A and FIG. 4B.

FIG. 6A is a first schematic diagram of a structure of adjacent pixel circuits within a pixel island of the display panel provided in FIG. 2A.

FIG. 6B is a second schematic diagram of a structure of adjacent pixel circuits within a pixel island of the display panel provided in FIG. 2A.

FIG. 7 is a first schematic diagram of a structure of a pixel island in the display panel provided in FIG. 2A.

FIG. 8 is a second schematic diagram of a structure of a pixel island in the display panel provided in FIG. 2A.

FIG. 9 is a third schematic diagram of a structure of a pixel island in the display panel provided in FIG. 2A.

FIG. 10 is a fourth schematic diagram of a structure of a pixel island in the display panel provided in FIG. 2A.

FIG. 11 is a first schematic diagram of a structure of the display panel provided in FIG. 2A.

FIG. 12 is a second schematic diagram of a structure of the display panel provided in FIG. 2A.

FIG. 13 is a third schematic diagram of a structure of the display panel provided in FIG. 2A.

FIG. 14 is an equivalent circuit diagram of the pixel drive circuit of the display panel provided in FIG. 2B.

FIG. 15 is a working timing diagram of the pixel drive circuit provided in FIG. 14.

FIG. 16 is a schematic diagram of a structure of adjacent pixel circuits in a pixel island of the display panel provided in FIG. 2B.

FIG. 17 is a first schematic diagram of a structure of a pixel island in the display panel provided in FIG. 2B.

FIG. 18 is a second schematic diagram of a structure of a pixel island in the display panel provided in FIG. 2B.

FIG. 19 is a third schematic diagram of a structure of a pixel island in the display panel provided in FIG. 2B.

FIG. 20 is a fourth schematic diagram of a structure of a pixel island in the display panel provided in FIG. 2B.

FIG. 21 is a first schematic diagram of a structure of the display panel provided in FIG. 2A.

FIG. 22 is a second schematic diagram of a structure of the display panel provided in FIG. 2A.

FIG. 23 is a third schematic diagram of a structure of the display panel provided in FIG. 2A.

### DETAILED DESCRIPTION

To make objectives, technical solutions, and advantages of the present disclosure clearer, the embodiments of the present disclosure will be described in detail with reference to the accompanying drawings. It is to be noted that implementations may be implemented in a plurality of different forms. Those of ordinary skills in the art may easily understand such a fact that implementations and contents may be transformed into various forms without departing from the purpose and scope of the present disclosure. Therefore, the present disclosure should not be explained as being limited to contents described in following implementations only. The embodiments in the present disclosure and features in the embodiments may be combined randomly with each other if there is no conflict. In order to keep the following description of the embodiments of the present disclosure clear and concise, detailed descriptions of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. The number of pixels in the display substrate and the number of sub-pixels in each pixel are not limited to the numbers shown in the drawings. The drawings described in the present disclosure are schematic structural diagrams only, and one implementation of the present disclosure is not limited to the shapes, numerical values or the like shown in the drawings.

Ordinal numerals such as “first”, “second”, and “third” in the specification are set to avoid confusion between constituent elements, but not to set a limit in quantity.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred device or element must have a particular orientation and be constructed and operated in the particular orientation. Therefore, they cannot be understood as limitations on the present disclosure. The positional relationships between the constituent elements may be changed as appropriate according to directions for describing the various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, a connection may be a fixed connection, or a detachable connection, or an integrated connection. It may be a mechanical connection or an electrical connection. It may be a direct mutual connection, or an indirect connection through middleware, or an internal communication between two elements. Those of ordinary skills in the art may understand specific meanings of these terms in the present disclosure according to specific situations.

In the specification, a transistor refers to an element which at least includes three terminals, i.e., a gate electrode, a drain electrode and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that, in the specification, the channel region refers to a region through which the current mainly flows.

In the specification, a first electrode may be a drain electrode, and a second electrode may be a source electrode. Or, the first electrode may be a source electrode, and the second electrode may be a drain electrode. In cases that transistors with opposite polarities are used, a current direction changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes a case that constituent elements are connected together through an element with a certain electrical effect. The “element with the certain electrical effect” is not particularly limited as long as electrical signals may be sent and received between the connected constituent elements. Examples of the “element with the certain electrical effect” not only include electrodes and wirings, but also include switch elements such as transistors, resistors, inductors, capacitors, other elements with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

In this specification, “being arranged in a same layer” refers to a structure formed by patterning two (or more than two) structures through a same patterning process, and their materials may be the same or different. For example, materials of precursors forming multiple structures arranged in a same layer are the same, and resultant materials may be the same or different.

A triangle, a rectangle, a parallelogram, a trapezoid, a pentagon and a hexagon in this specification are not strictly defined, and they may be an approximate triangle, a rectangle, a trapezoid, a pentagon or a hexagon, etc. There may be some small deformation caused by tolerance, and there may be a lead corner, a chamfer, a rounded corner, an arc edge, and a deformation, etc.

In the present disclosure, “about” refers to that a boundary is defined not so strictly and numerical values within process and measurement error ranges are allowed.

With a rapid development of three-dimensional stereoscopic display technology, Virtual Reality (VR for short), Augmented Reality (AR for short) and Mixed Reality (MR for short) have increasingly become important ways for human beings to obtain information, and also become new ways for human beings to interact with the world. Through wearable devices, such as VR glasses and VR helmets, images can be directly projected into the eyes of viewers, thus achieving an immersive display experience. Herein, the wearable device may include a display apparatus, including a plurality of pixel islands. Due to the low aperture ratio of pixel islands, the display effect of the display apparatus is poor.

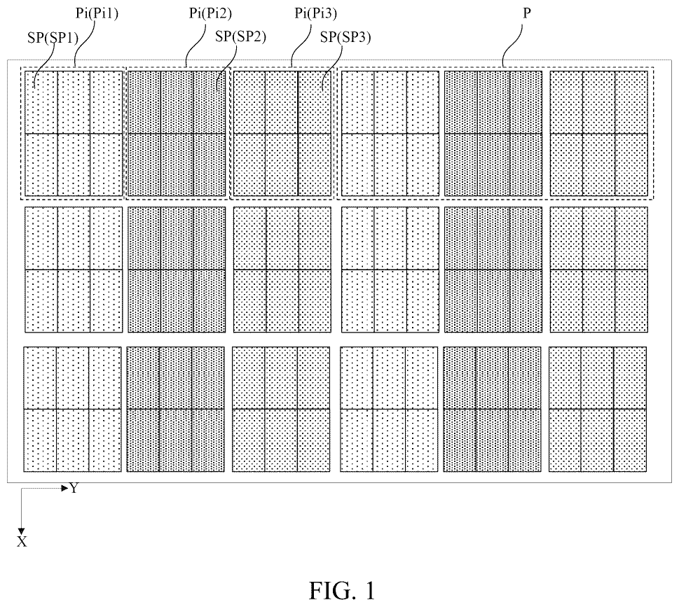

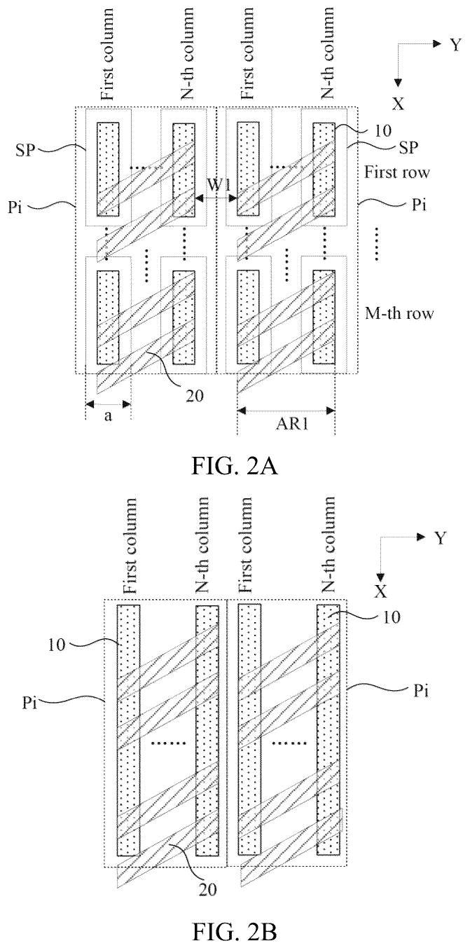

FIG. 1 is a schematic diagram of a structure of a display panel provided by an embodiment of the present disclosure, FIG. 2A is a first schematic diagram of a structure of two pixel islands in the display panel provided by an embodiment of the present disclosure, and FIG. 2B is a second schematic diagram of a structure of two pixel islands in the display panel provided by an embodiment of the present disclosure. As shown in FIG. 1, FIG. 2A and FIG. 2B, the display panel provided by embodiments of the present disclosure may include a substrate (not shown in the figure) and pixel islands Pi arranged in an array on the substrate. At least one pixel island Pi may include a plurality of pixel drive circuits 10 and a plurality of light emitting devices, a light emitting device includes a first electrode 20, and at least one pixel drive circuit 10 is electrically connected to at least one light emitting device.

In an exemplary implementation, first electrodes 20 of a plurality of light emitting devices in the same pixel island are arranged along a first direction X, and an orthographic projection of the first electrode 20 of at least one light emitting device on the substrate is at least partially overlapped with an orthographic projection of at least two pixel drive circuits 10 on the substrate.

In an exemplary implementation, the substrate may be a flexible substrate or a rigid substrate. The rigid substrate may include, but be not limited to, one or more of glass and quartz. The flexible substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers.

In an exemplary implementation, colors of light emitted by light emitting devices within the same pixel island may be the same or may be different, and the present disclosure is illustrated by taking a case where colors of light emitted by light emitting devices within the same pixel island are the same as an example.

In an exemplary implementation, the pixel islands Pi arranged in an array are referred to pixel islands arranged in an array along the first direction X and the second direction Y.

In an exemplary implementation, a shape of a pixel island may be a polygon, a curved shape or other irregular shapes, such as, exemplarily, a triangle, a square, a hexagon or a circle. FIG. 1, FIG. 2A and FIG. 2B are illustrated by taking a case where a shape of a pixel island is a quadrilateral as an example.

In an exemplary implementation, as shown in FIG. 1, the pixel drive circuit and the light emitting device may form a sub-pixel SP, the light emitting device is configured to emit light with a corresponding brightness in response to a current output by the pixel drive circuit of the sub-pixel where the light emitting device is located, and the pixel drive circuit located in the same sub-pixel corresponds to the light emitting device. The drivings of pixel drive circuits of different sub-pixels are arranged independently, or different sub-pixels may share the same pixel drive circuit. FIG. 2A is illustrated by taking a case where drivings of the pixel drive circuits of different sub-pixels are arranged independently as an example, and FIG. 2B is illustrated by taking a case where at least two sub-pixels may share the same pixel drive circuit as an example.

In an exemplary implementation, when the display panel is applied to a three-dimensional stereoscopic display, each sub-pixel in a pixel island may correspond to a view.

In an exemplary implementation, colors of light emitted by light emitting devices within the same pixel island are same, that is, a plurality of sub-pixels within the same pixel island are of the same color. In an exemplary implementation, the shape of the sub-pixel may be a polygon, a curved shape or other irregular shapes, such as a rectangular shape, a diamond, a pentagon or a hexagon.

In an exemplary implementation, the display panel may further include a drive circuit layer and a light emitting structure layer which are stacked sequentially on the substrate, wherein the drive circuit layer may include a pixel drive circuit, and a light emitting structure layer may include a light emitting device. The light emitting device may emit light with various colors. The light emitting device may further include an organic light emitting layer, and a second electrode arranged on a side of the organic light emitting layer away from the first electrode.

In an exemplary implementation, the first electrode may be made of a metal material or a transparent conductive material. The metal material may include any one or more of Argentum (Ag), Copper (Cu), Aluminum (Al), Titanium (Ti), and Molybdenum (Mo), or an alloy material of the above metals. The transparent conductive material may include Indium Tin Oxide (ITO) or Indium Zinc Oxide (IZO). In an exemplary implementation, the first electrode may have a single-layer structure or a multi-layer composite structure, such as ITO/AI/ITO.

In an exemplary implementation, the second electrode may be made of any one or more of Magnesium (Mg), Argentum (Ag), Aluminum (Al), Copper (Cu), and Lithium (Li), or an alloy made of any one or more of the above metals.

In an exemplary implementation, the organic emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, one or more of hole injection layers, hole transport layers, electron block layers, hole block layers, electron transport layers and electron injection layers of all sub-pixels may be connected together to form a common layer. The emitting layers of adjacent sub-pixels may overlap slightly with each other, or may be isolated from each other.

In an exemplary implementation, as shown in FIG. 2A and FIG. 2B, the first electrodes 20 of the light emitting devices within the pixel island may be arranged along the first direction, that is, arranged along a column direction, in another words, the pixel island may include one column of first electrodes 20 of light emitting devices therein, or may include a plurality of columns of first electrodes 20 of light emitting devices therein, which are not limited in this disclosure.

As shown in FIG. 2A, a length AR1 of opening of the light emitting device of the pixel island along the second direction satisfies a formula AR1=N*a−W1, wherein N is the number of sub-pixels included in the pixel island along the second direction Y, W1 is a spacing between the first electrodes of the light emitting devices between the pixel islands, and a is a length of sub-pixels along the second direction Y. When N=2, AR1=2a−W1.

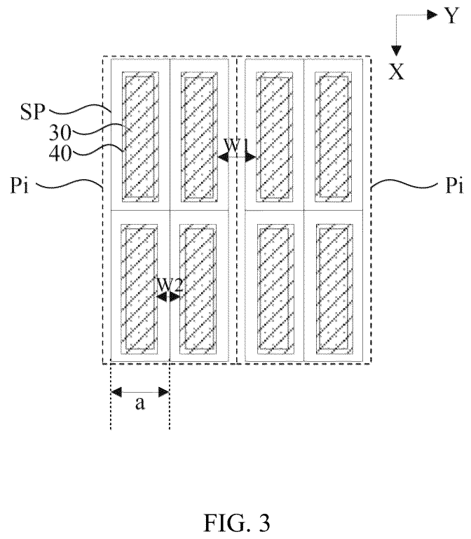

FIG. 3 is a schematic diagram of a structure of two pixel islands in a display panel. Each pixel island Pi in FIG. 3 includes 2*2 sub-pixels SPs, and each sub-pixel includes a pixel drive circuit 30, and a first electrode 40 of a light emitting device electrically connected to the pixel drive circuit. As shown in FIG. 3, the pixel drive circuits of the plurality of sub-pixels within the same pixel island are arranged in an array, the pixel drive circuits of different sub-pixels are arranged independently, and the first electrodes of light emitting devices of the plurality of sub-pixels within the same pixel island are arranged in an array. As shown in FIG. 3, a length AR2 of opening of the light emitting device of the pixel island along the second direction satisfies a formula AR2=a−(W1+W2)/2, wherein W1 is a spacing between first electrodes of the light emitting devices between the pixel islands, and W2 is a spacing between the first electrodes of the adjacent light emitting devices within the same pixel island along the second direction Y. In the pixel island provided in FIG. 3, when a is small and W1 and W2 are large, a length of the opening of the light emitting device of the pixel island along the second direction is small, that is, the aperture ratio of the pixel island is low.

Compared with the display panel provided in FIG. 3, the display panel provided in FIG. 2A has a different arrangement of the first electrodes of the light emitting devices within the same pixel island, such that the length of the openings of the light emitting devices of the pixel island along the second direction in the present disclosure is larger than the length of the openings of the light emitting devices of the pixel island along the second direction provided in FIG. 3, that is, an aperture ratio of the pixel island of the display panel provided in FIG. 2 is larger than an aperture ratio of the pixel island of the display panel provided in FIG. 3.

The display panel provided by the present disclosure includes a substrate, and pixel islands arranged in an array on the substrate. At least one pixel island includes a plurality of pixel drive circuits and a plurality of light emitting devices, wherein a light emitting device includes a first electrode. At least one pixel drive circuit is electrically connected with the first electrode of at least one light emitting device, the first electrodes of the plurality of light emitting devices within the same pixel island are arranged along a first direction, and an orthographic projection of the first electrode of the at least one light emitting device on the substrate is at least partially overlapped with an orthographic projection of at least two pixel drive circuits on the substrate. In the present disclosure, by making the first electrodes of a plurality of light emitting devices within the same pixel island be arranged along the first direction, and the orthographic projection of the first electrode of at least one light emitting device on the substrate be at least partially overlapped with the orthographic projection of at least two pixel drive circuits on the substrate, the length of opening of the light emitting device within the pixel island along the second direction is increased, and the aperture ratio of the pixel island is improved, further improving the display effect of the display panel.

In an exemplary implementation, as shown in FIG. 1, the pixel island Pi includes a first color pixel island Pi1, a second color pixel island Pi2 and a third color pixel island Pi3, and adjacent first color pixel island Pi1, second color pixel island Pi2 and third color pixel island Pi3, that are three adjacent pixel island, form one pixel P.

In an exemplary implementation, three pixel islands in the same pixel may be arranged in an L-shape or in a line-shape or in a shape of a Chinese character “ [symbol] ”.

In an exemplary implementation, as shown in FIG. 1, the first color pixel island Pi1, the second color pixel island Pi2, and the third color pixel island Pi3 located within the same pixel are arranged along the second direction Y, wherein the first direction X intersects with the second direction Y. Herein, the first direction X intersecting with the second direction Y means that an angle between the first direction and the second direction Y is about 70 degrees to 90 degrees. The first direction X and the second direction Y may be in a same plane.

In an exemplary implementation, the first color pixel island Pi1 may be a pixel island emitting red light, the second color pixel island Pi2 may be a pixel island emitting blue light, and the third color pixel island Pi3 may be a pixel island emitting green light.

In an exemplary implementation, as shown in FIG. 2A and FIG. 2B, a shape of the first electrode of the light emitting device may be a parallelogram.

In an exemplary implementation, as shown in FIG. 2A and FIG. 2B, an extension direction of short sides of the parallelogram is parallel to the first direction X, that is, the first electrode of the light emitting device may be an inclined parallelogram.

The shape of the first electrodes of the light emitting devices provided by the present disclosure makes an area of the first electrodes of the light emitting devices larger, which can not only avoid an electrical connection between the first electrode of the light emitting device and a wrong pixel drive circuit, but also achieve a larger light emitting area.

In an exemplary implementation, at least one pixel island includes K light emitting devices, and a plurality of pixel drive circuits included in the at least one pixel island are arranged in an arrangement of M rows and N columns, wherein the first direction is a column direction, the second direction intersecting with the first direction is a row direction, and M, N are positive integers greater than or equal to 1. FIG. 2A is illustrated by taking M>1 as an example, wherein when M>1, M*N=K, and FIG. 2B is illustrated by taking M=1.

In an exemplary implementation, as shown in FIG. 2A, when M>1, the pixel drive circuit at the i-th row and the j-th column is electrically connected to a first electrode of the light emitting device at the (N*(i−1)+j)-th row, where i and j are positive integers, and 1≤i≤M, 1≤j≤N. Exemplarily, when M=N−2, the pixel drive circuit at the first row and the first row is electrically connected to the first electrode of the light emitting devices at the first row, the pixel drive circuit at the first row and the second column is electrically connected to the first electrode of the light emitting device at the second row, the pixel drive circuit at the second row and the first column is electrically connected to the first electrode of the light emitting device at the third row, and the pixel drive circuit at the second row and the second column is electrically connected to the first electrode of the light emitting device at the fourth row.

In an exemplary implementation, when M>1, at least one pixel island further includes a plurality of light emitting control signal lines, and the pixel drive circuit includes a drive transistor and a light emitting control transistor. A control electrode of the light emitting control transistor is electrically connected to the light emitting control signal line, a first electrode of the light emitting control transistor is electrically connected to the drive transistor, and a second electrode of the light emitting control transistor is electrically connected to the first electrode of the light emitting device to which the pixel drive circuit is electrically connected.

In an exemplary implementation, when M>1, at least one pixel island may further include a plurality of reset signal lines, a plurality of scan signal lines, a plurality of initial signal lines, a plurality of first power supply lines, and a plurality of data signal lines.

In an exemplary implementation, at least one of the reset signal line, the scan signal line, the light emitting control signal line, and the initial signal line extends along a row direction. The data signal line and the first power supply line extend along a column direction.

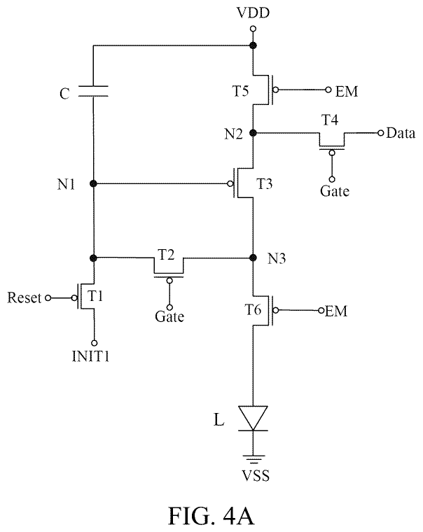

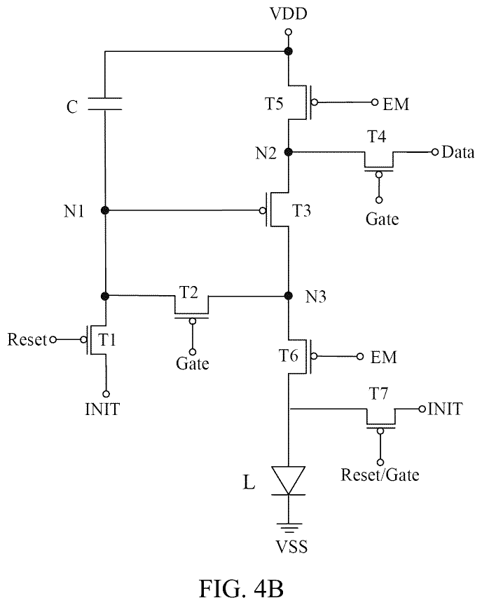

FIG. 4A is a first equivalent circuit diagram of a pixel drive circuit of the display panel provided in FIG. 2A, and FIG. 4B is a second equivalent circuit diagram of the pixel drive circuit of the display panel provided in FIG. 2A. When M>1, as shown in FIG. 4A and FIG. 4B, the pixel drive circuit at least includes a first transistor T1 to a sixth transistor T6. The first transistor is a node reset transistor, the second transistor is a compensation transistor, the third transistor is a drive transistor, the fourth transistor is a writing transistor, the fifth transistor is a light emitting transistor, and the sixth transistor is a light emitting control transistor.

In an exemplary implementation, as shown in FIG. 4A, the pixel drive circuit provided in FIG. 4A may include a first transistor T1 to a sixth transistor T6 and a capacitor C. For any of the pixel drive circuit, a control electrode of the first transistor T1 is electrically connected to a reset signal line Reset, a first electrode of the first transistor T1 is electrically connected to an initial signal line INIT, and a second electrode of the first transistor T1 is electrically connected to a first node N1; a control electrode of the second transistor T2 is electrically connected to a scan signal line Gate, a first electrode of the second transistor T2 is electrically connected to the first node N1, and a second electrode of the second transistor T2 is electrically connected to a third node N3; a control electrode of the third transistor T3 is electrically connected to the first node N1, a first electrode of the third transistor T3 is electrically connected to the second node N2, and a second electrode of the third transistor T3 is electrically connected to the third node N3; a control electrode of the fourth transistor T4 is electrically connected to the scan signal line Gate, a first electrode of the fourth transistor T4 is electrically connected to the data signal line Data, and a second electrode of the fourth transistor T4 is electrically connected to the second node N2; a control electrode of the fifth transistor T5 is connected to a light emitting signal line EM, a first electrode of the fifth transistor T5 is electrically connected to a first power supply line VDD, and a second electrode of the fifth transistor T5 is connected to the second node N2; a control electrode of the sixth transistor T6 is electrically connected to the light emitting signal line EM, a first electrode of the sixth transistor T6 is electrically connected to the third node N3, and a second electrode of the sixth transistor T6 is electrically connected to a first electrode of a light emitting element L to which the pixel drive circuit is electrically connected; and a first electrode plate of the capacitor C is connected to the first power supply line VDD, and a second electrode plate of the capacitor C is connected to the first node N1.

In an exemplary implementation, as shown in FIG. 4B, the pixel drive circuit provided in FIG. 4B includes a first transistor T1 to a seventh transistor T7 and a capacitor C. A connection relationship between the first transistor to the sixth transistor and the capacitor in FIG. 4B is the same as a connection relationship between the first transistor to the sixth transistor and the capacitor in FIG. 4. For any pixel drive circuit, the control electrode of the seventh transistor T7 is electrically connected to the Reset signal line Reset or the scan signal line Gate, the first electrode of the seventh transistor T7 is electrically connected to the initial signal line INIT, and the second electrode of the seventh transistor T7 is electrically connected to the first electrode of the light emitting device L.

In an exemplary implementation, an initial signal line to which the first electrode of the seventh transistor is connected may be a same signal line as an initial signal line to which the first electrode of the first transistor is connected, or may be a different signal line from an initial signal line to which the first electrode of the first transistor is connected. FIG. 4B is illustrated by taking a case where an initial signal line to which the first electrode of the seventh transistor is connected is a same signal line as an initial signal line to which the first electrode of the first transistor is connected as an example.

In an exemplary implementation, at least one pixel island may include M reset signal lines, M scan signal lines, M light emitting control signal lines, M initial signal lines, N first power supply lines, and N data signal lines. For the pixel drive circuit at the i-th row and the j-th column, a control electrode of the first transistor T1 is electrically connected to the i-th reset signal line Reset, a first electrode of the first transistor T1 is electrically connected to the i-th initial signal line INIT, and a second electrode of the first transistor T1 is electrically connected to a first node N1; a control electrode of the second transistor T2 is electrically connected to the i-th scan signal line Gate, a first electrode of the second transistor T2 is electrically connected to the first node N1, and a second electrode of the second transistor T2 is electrically connected to a third node N3; a control electrode of the third transistor T3 is electrically connected to the first node N1, a first electrode of the third transistor T3 is electrically connected to the second node N2, and a second electrode of the third transistor T3 is electrically connected to the third node N3; a control electrode of the fourth transistor T4 is electrically connected to the i-th scan signal line Gate, a first electrode of the fourth transistor T4 is electrically connected to the j-th data signal line Data, and a second electrode of the fourth transistor T4 is electrically connected to the second node N2; a control electrode of the fifth transistor T5 is connected to the i-th light emitting control signal line EM, a first electrode of the fifth transistor T5 is electrically connected to the j-th first power supply line VDD, and a second electrode of the fifth transistor T5 is connected to the second node N2; a control electrode of the sixth transistor T6 is electrically connected to the i-th light emitting control signal line EM, a first electrode of the sixth transistor T6 is electrically connected to the third node N3, and a second electrode of the sixth transistor T6 is electrically connected to a first electrode of a light emitting element L to which the pixel drive circuit of the i-th row and the j-th column is electrically connected; and a first electrode plate of the capacitor C is connected to the first power supply line VDD, and a second electrode plate of the capacitor C is connected to the first node N1.

In an exemplary implementation, when M is an even number, at least one pixel island may include M reset signal lines, M scan signal lines, M light emitting control signal lines, M initial signal lines, N/2 first power supply lines and N data signal lines, and in this case, the pixel drive circuits at the x-th column and the x+1 column share one first power supply line, and x is an odd or even number, wherein the first power supply line extends along the row direction. For the pixel drive circuit of the i-th row and the j-th column, a control electrode of the first transistor T1 is electrically connected to the i-th reset signal line Reset, a first electrode of the first transistor T1 is electrically connected to the i-th initial signal line INIT, and a second electrode of the first transistor T1 is electrically connected to a first node N1; a control electrode of the second transistor T2 is electrically connected to the i-th scan signal line Gate, a first electrode of the second transistor T2 is electrically connected to the first node N1, and a second electrode of the second transistor T2 is electrically connected to a third node N3; a control electrode of the third transistor T3 is electrically connected to the first node N1, a first electrode of the third transistor T3 is electrically connected to the second node N2, and a second electrode of the third transistor T3 is electrically connected to the third node N3; a control electrode of the fourth transistor T4 is electrically connected to the i-th scan signal line Gate, a first electrode of the fourth transistor T4 is electrically connected to the j-th data signal line Data, and a second electrode of the fourth transistor T4 is electrically connected to the second node N2; a control electrode of the fifth transistor T5 is connected to the i-th light emitting control signal line EM, a first electrode of the fifth transistor T5 is electrically connected to the y-th first power supply line VDD, and a second electrode of the fifth transistor T5 is connected to the second node N2; a control electrode of the sixth transistor T6 is electrically connected to the i-th light emitting control signal line EM, a first electrode of the sixth transistor T6 is electrically connected to the third node N3, and a second electrode of the sixth transistor T6 is electrically connected to a first electrode of a light emitting element L to which the pixel drive circuit at the i-th row and the j-th column is electrically connected; and a first electrode plate of the capacitor C is connected to the first power supply line VDD, and a second electrode plate of the capacitor C is connected to the first node N1; wherein y satisfies the following formula:

$$y = \{ \begin{matrix}\frac{j}{2} , j is an even \\ \frac{( j + 1 )}{2} , j is an odd\end{matrix}$$

In an exemplary implementation, the third transistor T3 may be referred to as a drive transistor, and the third transistor T3 determines a magnitude of a drive current flowing between the first power supply line VDD and the second power supply line VSS according to the potential difference between its control electrode and first electrode.

In an exemplary implementation, as shown in FIG. 4A and FIG. 4B, the second electrode of the light emitting device L is connected to a second power supply line VSS.

In an exemplary implementation, the first power supply line VDD continuously provides a high level signal, and the second power supply line VSS continuously provides a low level signal.

Distinguished by their characteristics, transistors may be divided into N-type transistors and P-type transistors. When the transistor is a P type transistor, its turn-on voltage is a low-level voltage (e.g., 0V, −5V, −10V or other suitable voltages) and its turn-off voltage is a high-level voltage (e.g., 5V, 10V or other suitable voltages). When the transistor is an N type transistor, its turn-on voltage is a high-level voltage (e.g., 5V, 10V or other suitable voltages) and its turn-off voltage is a low-level voltage (e.g., 0V, −5V, −10V or other suitable voltages).

In an exemplary implementation, all the transistors of the pixel drive circuit may be P-type transistors, or may be N-type transistors. Use of the same type of transistors in the pixel drive circuit may simplify a process flow, reduce the process difficulty of a display panel, and improve the product yield. In some possible implementations, all the transistors in the pixel drive circuit may include a P-type transistor and an N-type transistor.

In an exemplary implementation, all the transistors in the pixel drive circuit may be low temperature poly silicon thin film transistors, or may be oxide thin film transistors, or may be low temperature poly silicon thin film transistors and oxide thin film transistors. An active layer of a low temperature poly-silicon thin film transistor may be made of Low Temperature Poly-Silicon (LTPS for short), and an active layer of an oxide thin film transistor may be made of an oxide semiconductor (Oxide). The low temperature poly-silicon thin film transistor has advantages such as high migration rate and fast charging. The oxide thin film transistor has advantages such as low drain current. The low temperature poly-silicon thin film transistor and the oxide thin film transistor are integrated on one display substrate to form a Low Temperature Polycrystalline Oxide (LTPO for short) display substrate, so that advantages of the low temperature poly-silicon thin film transistor and the oxide thin film transistor can be utilized, low-frequency drive can be realized, power consumption can be reduced, and display quality can be improved.

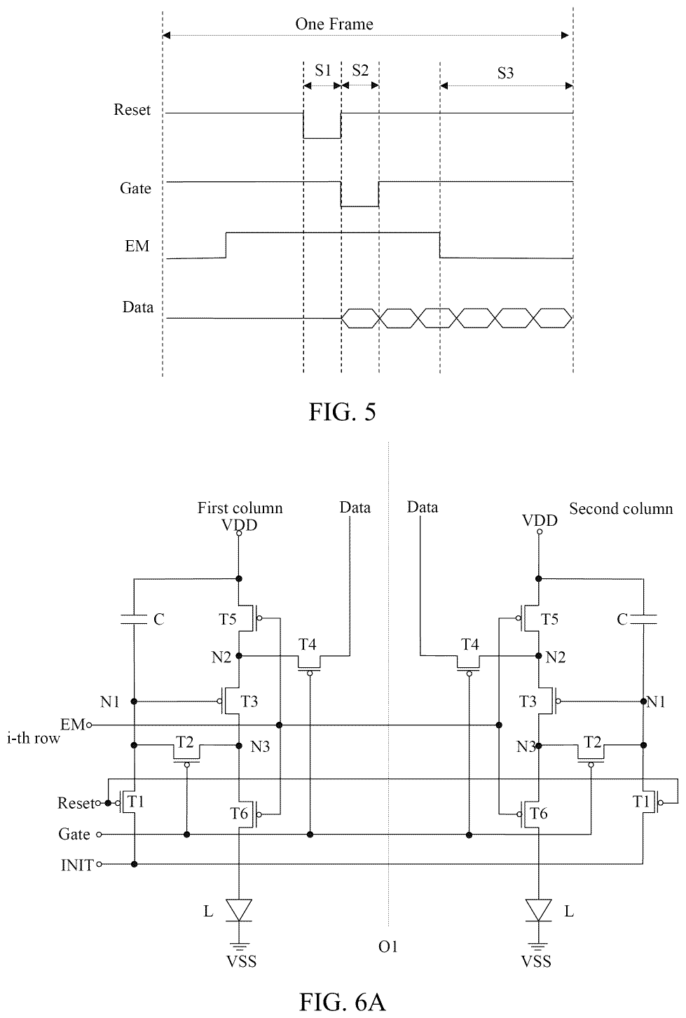

FIG. 5 is a working timing diagram of the pixel drive circuits provided in FIG. 4A and FIG. 4B. An exemplary implementation of the present disclosure will be described below through a working process of the pixel drive circuit exemplified in FIG. 4A. The pixel drive circuit in FIG. 4A includes six transistors (a first transistor T1 to a six transistor T6) and one capacitor C, and the six transistors are all P-type transistors.

In an exemplary implementation, as shown in FIG. 4A and FIG. 5, when one frame of image is displayed, the working process of the pixel drive circuit may include following stages.

In a first stage S1, referred to as a reset stage, a signal of the reset signal line Reset is a low-level signal, and signals of the scan signal line Gate and the light emitting control signal line EM are high-level signals. The signal of the reset signal line Reset is a low-level signal, so that the first transistor T1 is turned on, and a signal of the initial signal line INIT is provided to a first node N1 to initialize (reset) the capacitor C to clear original charges in the capacitor. The signals of the scan signal line Gate and the light emitting control signal line EM are the high-level signals, so that the second transistor T2, the fourth transistor T4, the fifth transistor T5, the sixth transistor T6, and the seventh transistor T7 are turned off. In this stage, the light emitting element L does not emit light.

In a second stage S2, referred to as a data writing stage or a threshold compensation stage, a signal of the scan signal line Gate is a low-level signal, signals of the reset signal line Reset and the light emitting control signal line EM are high-level signals, and the data signal line Data outputs a data voltage. In this stage, the second terminal of the capacitor C is at a low level, so the third transistor T3 is turned on. A signal of the scan signal line Gate is a low-level signal, so that the second transistor T2, the fourth transistor T4 and the seventh transistor T7 are turned on. The second transistor T2 and the fourth transistor T4 are turned on, such that the data voltage output by the data signal line Data is provided to the first node N1 through the second node N2, the turned-on third transistor T3, the third node N3 and the turned-on second transistor T2, and charge a difference between the data voltage output by the data signal line Data and a threshold voltage of the third transistor T3 into the capacitor C. The voltage of the second terminal (the first node N1) of the capacitor C is Vd−|Vth|, wherein Vd is the data voltage output by the data signal line Data, and Vth is the threshold voltage of the third transistor T3. The signal of the reset signal line Reset is a high-level signal, so that the first transistor T1 is turned off. The signal of the light emitting control signal line EM is the high-level signal, so that the fifth transistor T5 and the sixth transistor T6 are turned off.

In a third stage S3, referred to as a light emitting stage, the signal of the light emitting control signal line EM is a low-level signal, and the signals of the scan signal line Gate and the reset signal line Reset are both high-level signals. A signal of the light emitting control signal line EM is a low-level signal, such that the fifth transistor T5 and the sixth transistor T6 are turned on, and a power supply voltage output by the first power line VDD provides a drive voltage to the first electrode of the light emitting element L through the turned-on fifth transistor T5, third transistor T3, and sixth transistor T6 to drive the light emitting element L to emit light.

In a drive process of the pixel drive circuit, a drive current flowing through the third transistor T3 (drive transistor) is determined by a voltage difference between the gate electrode and the first electrode of the third transistor T3. Since the voltage of the first node N1 is Vdata−|Vth|, the drive current of the third transistor T3 is as follows.

$$I = K * {( Vgs - Vth )}^{2} = K * {[ ( Vdd - Vd + \vert Vth \vert ) - Vth ]}^{2} = K * {( Vdd - Vd )}^{2}$$

Herein, I is the drive current flowing through the third transistor T3, i.e., a drive current for driving the light emitting element L, K is a constant, Vgs is the voltage difference between the gate electrode and the first electrode of the third transistor T3, Vth is a threshold voltage of the third transistor T3, Vd is a data voltage output by the data signal line Data, and Vdd is a power voltage output by the first power supply line VDD.

It can be seen from the derivation result of the above current formula that in the light emitting stage, the drive current of the third transistor T3 is no longer affected by the threshold voltage of the fourth transistor T3. Therefore, the influence of the threshold voltage of the third transistor T3 on the drive current is eliminated, which can ensure uniformity of the display brightness of the display product, and improve the overall display effect of the display product.

When the seventh transistor is electrically connected to the reset signal line, the second and third stages in the working process of the pixel drive circuit provided in FIG. 4B are the same as the second and third stages in the working process of the pixel drive circuit provided in FIG. 4A, respectively. The difference between the working process of the pixel drive circuit provided in FIG. 4B and the working process of the pixel drive circuit provided in FIG. 4A lies in that the first stage in the working process of the pixel drive circuit provided in FIG. 4B further includes the seventh transistor T7 is turned on, the first electrode of the light emitting device L is reset, and the original charges in the first electrode of the light emitting device L are cleared. When the seventh transistor is electrically connected to the scan signal line, the first stage further includes that the seventh transistor T7 is turned on, the first electrode of the light emitting device L is reset, and the original charges in the first electrode of the light emitting device L are cleared.

When the seventh transistor is electrically connected to the scan signal line, the first and third stages in the working process of the pixel drive circuit provided in FIG. 4B are the same as the first and third stages in the working process of the pixel drive circuit provided in FIG. 4A, respectively. The difference between the working process of the pixel drive circuit provided in FIG. 4B and the working process of the pixel drive circuit provided in FIG. 4A lies in that that the second stage in the working process of the pixel drive circuit provided in FIG. 4B further includes that the seventh transistor T7 is turned on, the first electrode of the light emitting device L is reset, and the original charges in the first electrode of the light emitting device L are cleared. When the seventh transistor is electrically connected to the scan signal line, the first stage further includes that the seventh transistor T7 is turned on, the first electrode of the light emitting device L is reset, and the original charges in the first electrode of the light emitting device L are cleared.

In an exemplary implementation, adjacent column pixel drive circuits located in the same row may be mirror symmetrical with respect to a virtual straight line extending along the first direction.

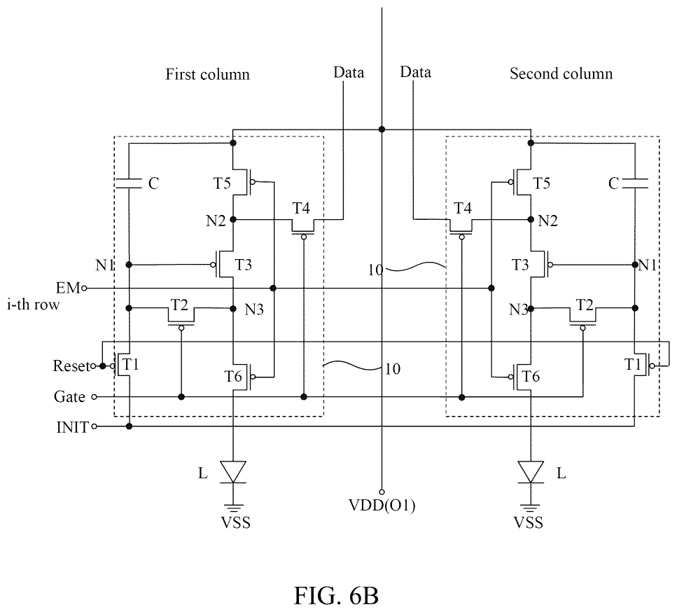

In an exemplary implementation, FIG. 6A is a first schematic diagram of a structure of adjacent pixel circuits within a pixel island of the display panel provided in FIG. 2A, and FIG. 6B is a second schematic diagram of a structure of an adjacent pixel circuits within a pixel island of the display panel provided in FIG. 2A. FIG. 6A is illustrated by taking a case where at least one pixel island may include M reset signal lines, M scan signal lines, M light emitting control signal lines, M initial signal lines, N first power supply lines, and N data signal lines as an example, and FIG. 6B is illustrated by taking a case where at least one pixel island may include M reset signal lines, M scan signal lines, M light emitting control signal lines, M initial signal lines, N/2 first power supply lines, and N data signal lines as an example. As shown in FIG. 6A and FIG. 6B, when N=2, the pixel drive circuit at the i-th row and the first column, and the pixel drive circuit at the i-th row and the second column are mirror symmetrical with respect to the virtual straight line O1 extending along the first direction X. The pixel drive circuit 10 at the i-th row and the first column, and the pixel drive circuit 10 at the i-th row and the second column are mirror symmetrical with respect to the virtual straight line O1 extending along the first direction X, which may make it more likely that an orthographic projection of the first electrode of the light emitting device on the substrate is overlapped with an orthographic projection of the pixel drive circuit, to which the light emitting device is electrically connected, on the substrate, and can be more beneficial for the electrical connection between the first electrode of the light emitting device and the corresponding pixel drive circuit.

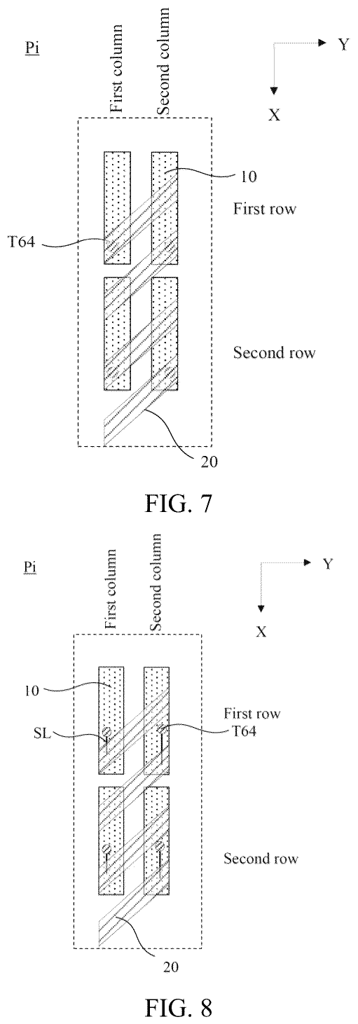

In an exemplary implementation, FIG. 7 is a first schematic diagram of a structure of a pixel island in the display panel provided in FIG. 2A. As shown in FIG. 7, an orthographic projection of a second electrode of a light emitting control transistor of any pixel drive circuit on the substrate may be at least partially overlapped with an orthographic projection of a first electrode of a light emitting device to which the light emitting control transistor is electrically connected on the substrate, i.e., an orthographic projection of a second electrode T64 of a light emitting control transistor of the pixel drive circuit 10 at the i-th row and the j-th column on the substrate is at least partially overlapped with an orthographic projection of a first electrode 20 of a light emitting device to which the pixel drive circuit at the i-th row and the j-th column is electrically connected on the substrate, i.e., orthographic projections of the second electrodes T64 of the light emitting control transistors of all the pixel drive circuits within the pixel island on the substrate is at least partially overlapped with orthographic projections of the first electrodes 20 of the light emitting devices to which the pixel drive circuits are electrically connected on the substrate. FIG. 7 is illustrated by taking M=N=2 as an example.

In an exemplary implementation, FIG. 8 is a second schematic diagram of a structure of a pixel island in the display panel provided in FIG. 2A. As shown in FIG. 8, an orthographic projection of a second electrode of a light emitting control transistor of any of the pixel drive circuit on a substrate may not be overlapped with an orthographic projection of a first electrode of the light emitting device to which the light emitting control transistor is electrically connected on the substrate. That is, an orthographic projection of the second electrode of the light emitting control transistor of the pixel drive circuit at the i-th row and the j-th column on the substrate is not overlapped with an orthographic projection of the first electrode of the light emitting device to which the pixel drive circuit at the i-th row and the j-th column is electrically connected on the substrate, that is, orthographic projections of the second electrodes T64 of the light emitting control transistors of all the pixel drive circuits within the pixel island on the substrate are not overlapped with orthographic projections of the first electrodes 20 of the light emitting devices to which the pixel drive circuits are electrically connected on the substrate. FIG. 8 is illustrated by taking M=N=2 as an example.

In an exemplary implementation, as shown in FIG. 8, when the orthographic projection of the second electrode of the light emitting control transistor of the pixel drive circuit at the i-th row and the j-th column on the substrate is not overlapped with the orthographic projection of the first electrode of the light emitting device to which the pixel drive circuit at the i-th row and the j-th column is electrically connected on the substrate, at least one pixel island may further include a plurality of signal connection lines SL, wherein a signal connection line SL is electrically connected to the second electrode T64 of the light emitting control transistor of the pixel drive circuit and the first electrode 20 of the light emitting device to which the pixel drive circuit is electrically connected.

In an exemplary implementation, as shown in FIG. 8, the signal connection line SL is arranged in a film layer between the film layer where the second electrode of the light emitting control transistor is located and the film layer where the first electrode is located.

In an exemplary implementation, the signal connection line SL may be a metal conductive line or a metal oxide conductive line. Exemplarily, a manufacturing material of the metal oxide conductive line may be indium tin oxide or zinc tin oxide, and the metal oxide conductive line is a transparent conductive line.

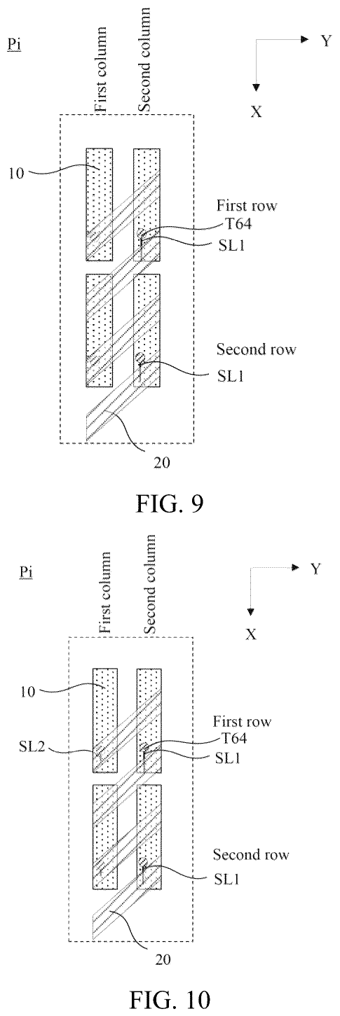

In an exemplary implementation, FIG. 9 is a third schematic diagram of a structure of a pixel island in the display panel provided in FIG. 2A, and FIG. 10 is a fourth schematic diagram of a structure of a pixel island in the display panel provided in FIG. 2A. As shown in FIG. 9 and FIG. 10, the pixel drive circuit may include a first pixel drive circuit and a second pixel drive circuit. An orthographic projection of the second electrode of the light emitting control transistor of the first pixel drive circuit on the substrate is not overlapped with an orthographic projection of the first electrode of the light emitting device, to which the first pixel drive circuit is electrically connected, on the substrate, an orthographic projection of the second electrode of the light emitting control transistor of the second pixel drive circuit on the substrate is at least partially overlapped with an orthographic projection of the first electrode of the light emitting device, to which the second pixel drive circuit is electrically connected, on the substrate, that is, an orthographic projection of the second electrodes T64 of the light emitting control transistors of one portion of pixel drive circuits within the pixel island on the substrate is at least partially overlapped with an orthographic projection of the first electrodes 20 of the light emitting devices, to which the pixel drive circuits are electrically connected, on the substrate, and an orthographic projection of the second electrodes T64 of the light emitting control transistors of the other portion of pixel drive circuits within the pixel island on the substrate is not overlapped with an orthographic projection of the first electrodes 20 of the light emitting devices, to which the pixel drive circuits are electrically connected, on the substrate. FIG. 9 and FIG. 10 are illustrated by taking M=N=2 as an example. FIG. 9 and FIG. 10 are illustrated by taking a case where the pixel drive circuit at the first row and the first column and the pixel drive circuit at the second row and the first column are the second pixel drive circuits, and the pixel drive circuit at the first row and second column and the pixel drive circuit at the second row and second column are the first pixel drive circuits as an example.

In an exemplary implementation, as shown in FIG. 9 and FIG. 10, at least one pixel island may further include a plurality of first signal connection lines SL1, wherein the first signal connection line SL1 is electrically connected to a second electrode T64 of the light emitting control transistor of the first pixel drive circuit and a first electrode 20 of the light emitting device to which the first pixel drive circuit is electrically connected.

In an exemplary implementation, the first signal connection line SL1 may be arranged in a film layer between a film layer where the second electrode of the light emitting control transistor of the pixel drive circuit is located and a film layer where the first electrode of the light emitting device to which the pixel drive circuit is electrically connected is located.

In an exemplary implementation, the first signal connection line SL1 may be a metal conductive line or a metal oxide conductive line. Exemplarily, a manufacturing material of the metal oxide conductive line may be indium tin oxide or zinc tin oxide, and the metal oxide conductive line is a transparent conductive line.

In an exemplary implementation, as shown in FIG. 10, the at least one pixel island further includes a plurality of second signal connection lines SL2, wherein the second signal connection line SL2 is electrically connected to the second electrode T64 of the light emitting control transistor of the second pixel drive circuit and the first electrode 20 of the light emitting device to which the second pixel drive circuit is electrically connected.

In an exemplary implementation, the second signal connection line SL2 may be arranged on a same layer as the first signal connection line SL1.

In an exemplary implementation, the second signal connection line SL2 may be a metal conductive line or a metal oxide conductive line. Exemplarily, a manufacturing material of the metal oxide conductive line may be indium tin oxide or zinc tin oxide, and the metal oxide conductive line is a transparent conductive line.

In an exemplary implementation, the second signal connection line SL2 may serve as a connection electrode between the first electrode of the light emitting device and the electrically connected pixel drive circuit, which may avoid a depth of a via exposing the second electrode of the light emitting control transistor of the pixel drive circuit being larger when the first electrode of the light emitting device is directly connected with the second electrode of the light emitting control transistor of the electrically connected pixel drive circuit, improving the reliability of the display panel.

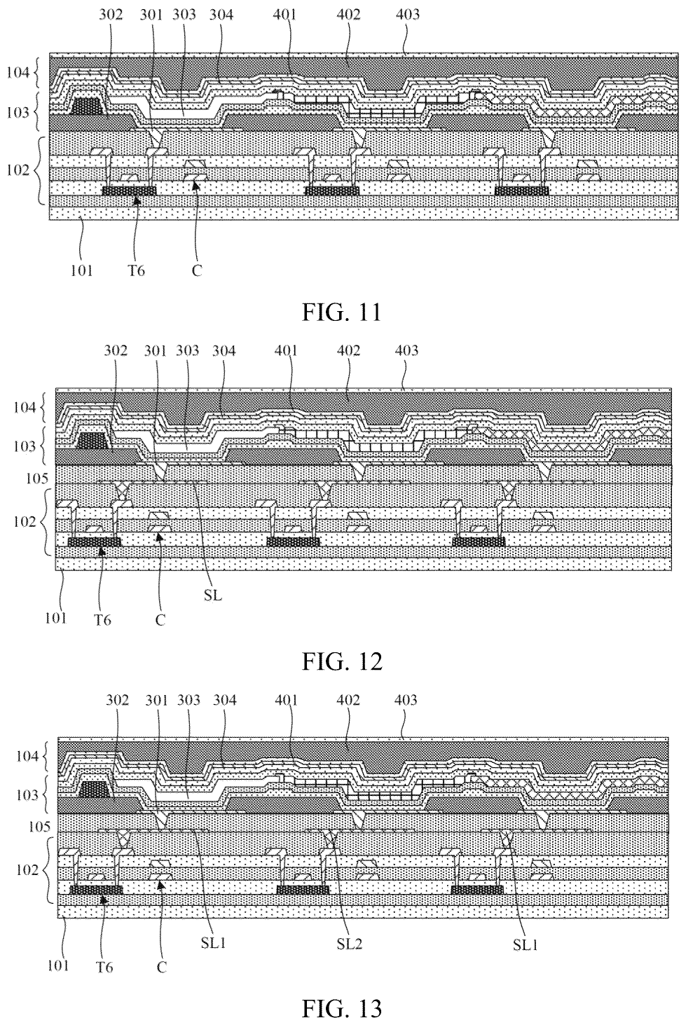

FIG. 11 is a first schematic diagram of a structure of the display panel provided in FIG. 2A, FIG. 12 is a second schematic diagram of a structure of the display panel provided in FIG. 2A. FIG. 13 is a third schematic diagram of a structure of the display panel provided in FIG. 2A. FIG. 11 to FIG. 13 illustrate structures of three sub-pixels within pixel islands of display panels. FIG. 11 to FIG. 13 are illustrated by taking N greater than or equal to 3 as an example, and in actual applications, N may be a positive integer greater than or equal to 2. As shown in FIG. 11 to FIG. 13, on a plane perpendicular to the display substrate, the display panel may include a drive circuit layer 102 arranged on a substrate 101, a light emitting structure layer 103 arranged on a side of the drive circuit layer 102 away from the substrate 101, and an encapsulation structure layer 104 arranged on a side of the light emitting structure layer 103 away from substrate 101.

In an exemplary implementation, the display substrate may include another film layer, such as a touch control structure layer, which is not limited in the present disclosure.

In an exemplary implementation, the substrate 101 may be a flexible substrate, or a rigid substrate.

In an exemplary implementation, the drive circuit layer 102 of each sub-pixel may include multiple transistors and a capacitor forming a pixel drive circuit. FIG. 11 to FIG. 13 are illustrated by taking a light emitting control transistor T6 and one capacitor C as an example. The light emitting structure 103 may include a first electrode 301, a pixel definition layer 302, an organic light emitting layer 303 and a second electrode 304. The first electrode 301 is connected with a second electrode of a light emitting control transistor T6 through a via, the organic light emitting layer 303 is connected with the first electrode 301, the second electrode 304 is connected with the organic light emitting layer 303, and the organic light emitting layer 303 emits light of a corresponding color under the drive of the first electrode 301 and the second electrode 304.

In an exemplary implementation, the encapsulation structure layer 104 may include a first encapsulation layer 401, a second encapsulation layer 402, and a third encapsulation layer 403 that are stacked. The first encapsulation layer 401 and the third encapsulation layer 403 may be made of an inorganic material, and the second encapsulation layer 402 may be made of an organic material. The second encapsulation layer 402 is arranged between the first encapsulation layer 401 and the third encapsulation layer 403, which can ensure that external moisture cannot enter the light emitting structure layer 103. Exemplarily, the first encapsulation layer and the third encapsulation layer may be made of any one or more of the following: Silicon Oxide (SiOx), Silicon Nitride (SiNx), and Silicon Oxynitride (SiON), may be a single layer, a multi-layer, or a composite layer, may adopt Chemical Vapor Deposition (CVD), or Atomic Layer Deposition (ALD), etc., thus can ensure that external water and oxygen cannot enter the emitting structure layer. The second encapsulation layer may be made of a resin, which plays a role of covering various film layers of the display region, so as to improve structural stability and planarization. In this way, the first encapsulation layer, the second encapsulation layer, and the third encapsulation layer that are stacked form the encapsulation structure layer, and the formed laminated structure of an inorganic material/an organic material/an inorganic material can ensure integrity of encapsulation and effectively isolate external water and oxygen.

In an exemplary implementation, the touch structure layer may include a first touch insulation layer arranged on the encapsulation structure layer, a first touch metal layer arranged on the first touch insulation layer, a second touch insulation layer covering the first touch metal layer, a second touch metal layer arranged on the second touch insulation layer, and a touch protection layer covering the second touch metal layer. The first touch metal layer may include a plurality of bridge electrodes, the second touch metal layer may include a plurality of first and second touch electrodes, and the first or second touch electrodes may be connected to the bridge electrodes through vias.

FIG. 11 is illustrated by taking a case where an orthographic projection of a second electrode T64 of a light emitting control transistor of the pixel drive circuit 10 at the i-th row and the j-th column on the substrate is at least partially overlapped with an orthographic projection of a first electrode 20 of a light emitting device to which the pixel drive circuit at the i-th row and the j-th column is electrically connected on the substrate as an example, and in this case, the second electrode T64 of the light emitting control transistor of the pixel drive circuit 10 at the i-th row and the j-th column are directly electrically connected to the first electrode 20 of the light emitting device to which the pixel drive circuit at the i-th row and j-th column is electrically connected.

FIG. 12 is illustrated by taking a case where an orthographic projection of a second electrode T64 of a light emitting control transistor of the pixel drive circuit 10 at the i-th row and the j-th column on the substrate is not overlapped with an orthographic projection of a first electrode 20 of a light emitting device to which the pixel drive circuit at the i-th row and the j-th column is electrically connected on the substrate as an example, and in this case, the display panel may further include a conductive connection layer 105 arranged between the drive circuit layer 102 and the light emitting structure layer 103, and the conductive connection layer 105 includes a signal connection line SL.

FIG. 13 is illustrated by taking a case where an orthographic projection of the second electrodes T64 of the light emitting control transistors of one portion of the pixel drive circuits within the pixel island on the substrate is overlapped at least partially with an orthographic projection of the first electrodes 20 of the light emitting devices to which the pixel drive circuits are electrically connected on the substrate, and an orthographic projection of the second electrodes T64 of the light emitting control transistors of the other portion of the pixel drive circuits on the substrate is not overlapped with an orthographic projection of the first electrodes 20 of the light emitting devices to which the pixel drive circuits are electrically connected on the substrate as an example, and in this case, the display panel may further include a conductive connection layer 105 arranged between the drive circuit layer 102 and the light emitting structure layer 103, and the conductive connection layer 105 includes a first signal connection line SL1 and a second signal connection line SL2.

In an exemplary implementation, the conductive connection layer may be made of a metal material or a transparent conductive material, and the metal material may include any one or more of Argentum (Ag), Copper (Cu), Aluminum (Al), Titanium (Ti), and Molybdenum (Mo), or an alloy material of the above metals, and the transparent conductive material may include Indium Tin Oxide (ITO) or Indium Zinc Oxide (IZO). In an exemplary implementation, the conductive connection layer may have a single-layer structure or a multi-layer composite structure, such as ITO/AI/ITO.

In an exemplary implementation, an insulation layer is provided between the conductive connection layer and the drive circuit layer, and an insulation layer is also provided between the conductive connection layer and the light emitting structure layer.

In an exemplary implementation, the insulation layer may be made of any one or more of silicon oxide (SiOx), silicon nitride (SiNx) and silicon oxynitride (SiON), and may be a single layer, a multi-layer or a composite layer.

In an exemplary implementation, as shown in FIG. 2B, when M=1, each pixel drive circuit may be electrically connected to K/N light emitting devices.

In an exemplary implementation, the pixel drive circuit at the j-th column is electrically connected to a first electrode of a light emitting device at the (1+K*(j−1)/N)-th row to a first electrode of a light emitting device at the (Kj/N)-th row, respectively, wherein j is a positive integer, and 1<j≤N. Exemplarily, when K=6 and N=2, the pixel drive circuits at the first row are electrically connected with a first electrode of a light emitting device at the first row, a first electrode of a light emitting device at the third row, and a first electrode of a light emitting device at the fifth row, and the pixel drive circuits at the second column are electrically connected with a first electrode of a light emitting device at the second row, a first electrode of a light emitting device at the fourth row, and a first electrode of a light emitting device at the sixth row.

In an exemplary implementation, when M=1, at least one pixel island further includes: K/N light emitting signal lines, and the pixel drive circuit includes a drive transistor and K/N light emitting control transistors, wherein the K/N light emitting control transistors are arranged along the first direction; a control electrode of the k-th light emitting control transistor is electrically connected with the k-th light emitting signal line, a first electrode of the k-th light emitting control transistor is electrically connected with the drive transistor, and a second electrode of the k-th light emitting control transistor is electrically connected with the k-th light emitting device to which the pixel drive circuit is electrically connected, wherein k is a positive integer, and 1≤k≤K/N.

In an exemplary implementation, when M=1, at least one pixel island may further include one reset signal line, one scan signal line, one light emitting control signal line, an initial signal line, at least one first power supply line, and N data signal lines.

In an exemplary implementation, at least one of the reset signal line, the scan signal line, the light emitting control signal line, the light emitting signal line, and the initial signal line extends along the row direction. The data signal line and the first power supply line extend along a column direction.

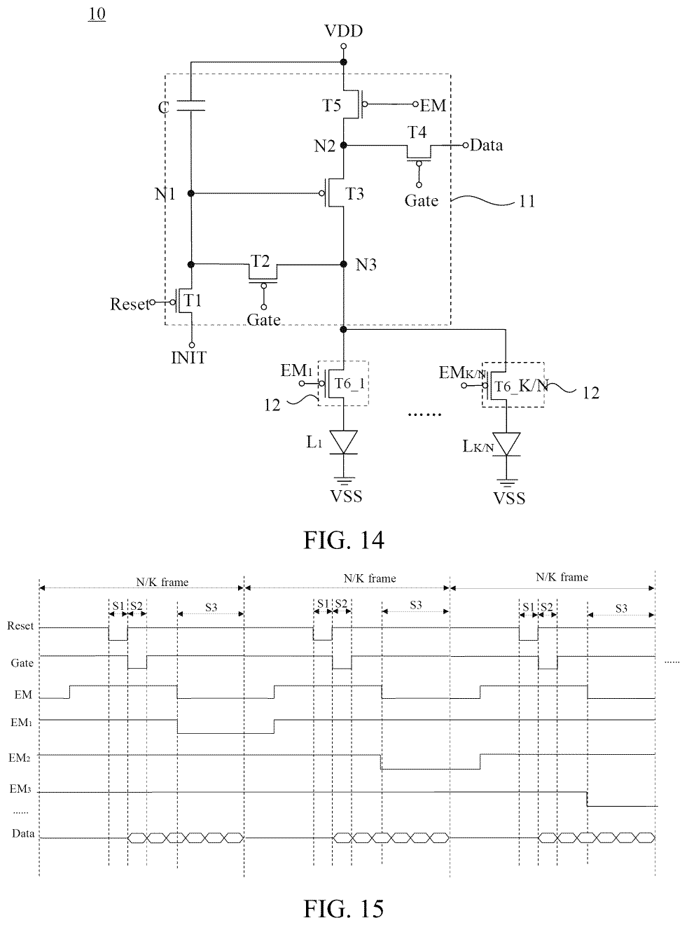

FIG. 14 is an equivalent circuit diagram of the pixel drive circuit of the display panel provided in FIG. 2B. As shown in FIG. 14, when at least one pixel island includes pixel drive circuits 10 of one row and N columns and light emitting devices of K rows and one column, the pixel drive circuit may at least include a first transistor T1 to a fifth transistor T5, and K/N sixth transistors T6_1 to T6_K/N. Among them, the first transistor is a node reset transistor, the second transistor is a compensation transistor, the third transistor is a drive transistor, the fourth transistor is a writing transistor, the fifth transistor is a light emitting transistor, the sixth transistor is a light emitting control transistor, the first transistor T1 to the fifth transistor T5 form a main drive circuit 11 of the pixel drive circuit, and each sixth transistor is referred to as a sub-drive circuit 12 of the pixel drive circuit.

As shown in FIG. 14, for any pixel drive circuit, a control electrode of the first transistor T1 is electrically connected to a reset signal line Reset, a first electrode of the first transistor T1 is electrically connected to an initial signal line INIT, and a second electrode of the first transistor T1 is electrically connected to a first node N1; a control electrode of the second transistor T2 is electrically connected to a scan signal line Gate, a first electrode of the second transistor T2 is electrically connected to the first node N1, and a second electrode of the second transistor T2 is electrically connected to a third node N3; a control electrode of the third transistor T3 is electrically connected to the first node N1, a first electrode of the third transistor T3 is electrically connected to the second node N2, and a second electrode of the third transistor T3 is electrically connected to the third node N3; a control electrode of the fourth transistor T4 is electrically connected to the scan signal line Gate, a first electrode of the fourth transistor T4 is electrically connected to the j-th data signal line Data, a second electrode of the fourth transistor T4 is electrically connected to a second node N2; a control electrode of the fifth transistor T5 is electrically connected to the light emitting control signal line EM, a first electrode of the fourth transistor T5 is electrically connected to the first power supply line VDD, and a second electrode of the fifth transistor T5 is electrically connected to the second node N2; a control electrode of the k-th transistor T6_k is electrically connected to the k-th light emitting signal line EMk, a first electrode of the k-th sixth transistor T6_k is electrically connected to the third node N3, and a second electrode of the k-th sixth transistor T6_k is electrically connected to a first electrode of the k-th light emitting device L to which the pixel drive circuit at the j-th column is electrically connected.

In an exemplary implementation, the pixel island may include N first power supply lines or N/2 first power supply lines. When N first power supply lines are included, first electrode of the first transistor of the pixel drive circuit at the j-th column is electrically connected to the j-th first power supply line, and when the N/2 first power supply lines are included, first electrode of the first transistor of the pixel drive circuit at the j-column is electrically connected to the y-th first power supply line, wherein y satisfies the following formula:

$$y = \{ \begin{matrix}\frac{j}{2} , j is an even \\ \frac{( j + 1 )}{2} , j is an odd\end{matrix}$$

In an exemplary implementation, the third transistor T3 may be referred to as a drive transistor, and the third transistor T3 determines a magnitude of a drive current flowing between the first power supply line VDD and the second power supply line VSS according to the potential difference between its control electrode and first electrode.

In an exemplary implementation, as shown in FIG. 14, a second electrode of the light emitting device L is connected to the second power supply line VSS.

In an exemplary implementation, the first power supply line VDD continuously provides a high level signal, and the second power supply line VSS continuously provides a low level signal.

Distinguished by their characteristics, transistors may be divided into N-type transistors and P-type transistors. When the transistor is a P type transistor, its turn-on voltage is a low-level voltage (e.g., 0V, −5V, −10V or other suitable voltages) and its turn-off voltage is a high-level voltage (e.g., 5V, 10V or other suitable voltages). When the transistor is an N type transistor, its turn-on voltage is a high-level voltage (e.g., 5V, 10V or other suitable voltages) and its turn-off voltage is a low-level voltage (e.g., 0V, −5V, −10V or other suitable voltages).

In an exemplary implementation, all the transistors of the pixel drive circuit may be P-type transistors, or may be N-type transistors. Use of the same type of transistors in the pixel drive circuit may simplify a process flow, reduce the process difficulty of a display panel, and improve the product yield. In some possible implementations, all the transistors in the pixel drive circuit may include a P-type transistor and an N-type transistor.

In an exemplary implementation, all the transistors in the pixel drive circuit may be low temperature poly silicon thin film transistors, or may be oxide thin film transistors, or may be low temperature poly silicon thin film transistors and oxide thin film transistors. An active layer of a low temperature poly-silicon thin film transistor may be made of Low Temperature Poly-Silicon (LTPS for short), and an active layer of an oxide thin film transistor may be made of an oxide semiconductor (Oxide). The low temperature poly-silicon thin film transistor has advantages such as high migration rate and fast charging. The oxide thin film transistor has advantages such as low drain current. The low temperature poly-silicon thin film transistor and the oxide thin film transistor are integrated on one display substrate to form a Low Temperature Polycrystalline Oxide (LTPO for short) display substrate, so that advantages of the low temperature poly-silicon thin film transistor and the oxide thin film transistor can be utilized, low-frequency drive can be realized, power consumption can be reduced, and display quality can be improved.

In an exemplary implementation, when the signal of one light emitting signal line is an effective level signal, the signals of other light emitting signal lines are all ineffective level signals except that the light emitting signal line whose signal is an effective level.

In an exemplary implementation, Time for which a signal of any one light emitting signal line is an effective level signal is partially overlapped with time for which a signal of the light emitting control signal line is an effective level signal.

FIG. 15 is a working timing diagram of the pixel drive circuit provided in FIG. 14. An exemplary implementation of the present disclosure will be described below through an working process of the pixel drive circuit exemplified in FIG. 14 in which all transistors are P-type transistors.

In an exemplary implementation, as shown in FIG. 14 and FIG. 15, when one-frame image display includes N/K-frames the number of which is K/N, and when a K-th N/K-frame image is displayed, the working process of the pixel drive circuit may include following stages.

In a first stage S1, referred to as a reset stage, a signal of the reset signal line Reset is a low-level signal, and signals of the scan signal line Gate, the light emitting control signal line EM and all the light emitting signal lines EM1 to EMK/N are high-level signals. The signal of the reset signal line Reset is a low-level signal, so that the first transistor T1 is turned on, and a signal of the initial signal line INIT is provided to a first node N1 to initialize (reset) the capacitor C to clear original charges in the capacitor. The signals of the scan signal line Gate, the light emitting control signal line EM, and all the light emitting signal lines EM1 to EMK/N are high-level signals, so that the second transistor T2, the fourth transistor T4, the fifth transistor T5, and the K/N sixth transistors T6 are turned off. In this stage, the light emitting element L does not emit light.

In a second stage S2, referred to as a data writing stage or a threshold compensation stage, a signal of the scan signal line Gate is a low-level signal, and signals of the reset signal line

Reset, the light emitting control signal line EM and all the light emitting signal lines EM1 to EMM are high-level signals, and the data signal line Data outputs a data voltage. In this stage, the second terminal of the capacitor C is at a low level, so the third transistor T3 is turned on. A signal of the scan signal line Gate is a low-level signal, so that the second transistor T2, the fourth transistor T4 and the seventh transistor T7 are turned on. The second transistor T2 and the fourth transistor T4 are turned on, so that the data voltage output by the data signal line Data is provided to the first node N1 through the second node N2, the turned-on third transistor T3, the third node N3 and the turned-on second transistor T2, and charge the difference between the data voltage output by the data signal line Data and the threshold voltage of the third transistor T3 into the capacitor C. The voltage of the second terminal (the first node N1) of the capacitor C is Vd-|Vth|, wherein Vd is the data voltage output by the data signal line Data and Vth is the threshold voltage of the third transistor T3. The signal of the reset signal line Reset is a high-level signal, so that the first transistor T1 is turned off. The signal of the light emitting control signal line EM is a high-level signal, so that the fifth transistor T5 is turned off. The signals of all the light emitting signal lines EM₁ to EM_{K/N} are high-level signals, and K/N sixth transistors T6 are turned off.

In the third stage S3, referred to as a light emitting stage, the signals of the light emitting control signal line EM and the k-th light emitting signal line EMK are low-level signals, and the signals of the scan signal line Gate, the reset signal line Reset and the other light emitting signal lines except the k-th light emitting signal line EMR are high-level signals. The signal of the light emitting control signal line EM is a low-level signal, so that the fifth transistor T5 is turned on, and the signal of the k-th light emitting signal line EMK is a low-level signal, so that the k-th sixth transistor T6_k is turned on, a power supply voltage output by the first power line VDD provides a drive voltage to the first electrode of the light emitting element L through the turned-on fifth transistor T5, third transistor T3, and k-th sixth transistor T6_k to drive the light emitting element Lx to emit light. Exemplarily, in the first N/K sub-frames, the signal of the first light emitting signal line EM₁ is a low-level signal, the first sixth transistor T6_1 is turned on, and the other sixth transistors are turned off. In the second N/K sub-frames, the signal of the second light emitting signal line EM₂ is a low-level signal, the second sixth transistor T6_2 is turned on, and the other sixth transistors are turned off.

In a drive process of the pixel drive circuit, a drive current flowing through the third transistor T3 (drive transistor) is determined by a voltage difference between the gate electrode and the first electrode of the third transistor T3. Since the voltage of the first node N1 is Vdata−|Vth|, the drive current of the third transistor T3 is as follows.

$$I = K * {( Vgs - Vth )}^{2} = K * {[ ( Vdd - Vd + \vert Vth \vert ) - Vth ]}^{2} = K * {( Vdd - Vd )}^{2}$$

Herein, I is the drive current flowing through the third transistor T3, i.e., a drive current for driving the light emitting element L, K is a constant, Vgs is the voltage difference between the gate electrode and the first electrode of the third transistor T3, Vth is a threshold voltage of the third transistor T3, Vd is a data voltage output by the data signal line Data, and Vdd is a power voltage output by the first power supply line VDD.

It can be seen from the derivation result of the above current formula that in the light emitting stage, the drive current of the third transistor T3 is not affected by the threshold voltage of the third transistor T3. Therefore, the influence of the threshold voltage of the third transistor T3 on the drive current is eliminated, which can ensure uniformity of the display brightness of the display product, and improve the overall display effect of the display product.

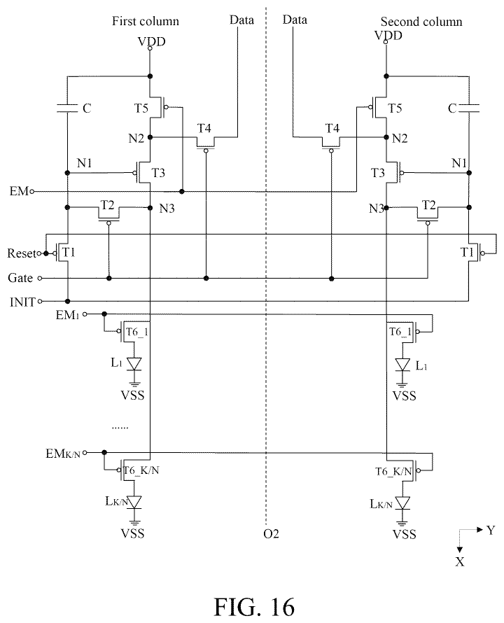

In an exemplary implementation, FIG. 16 is a schematic diagram of a structure of adjacent pixel circuits within a pixel island of the display panel provided in FIG. 2B. As shown in FIG. 16, the K/N sixth transistors in the pixel drive circuit are arranged along the first direction X. The arrangement of the K/N sixth transistors in the pixel drive circuit along the first direction X may facilitate an electrical connection with the first electrode of the light emitting device.

In an exemplary implementation, adjacent column pixel drive circuits located in the same row are mirror symmetrical with respect to a virtual straight line extending along the first direction.

In an exemplary implementation, as shown in FIG. 16, when N=2, the pixel drive circuits at the first column and the pixel drive circuits at the second column are mirror symmetrical with respect to a virtual straight line O2 extending along the first direction X. The pixel drive circuits 10 at the first column and the pixel drive circuits 10 at the second column are mirror symmetrical with respect to the virtual straight line O2 extending along the first direction X, which can make it more likely that an orthographic projection of the first electrode of the light emitting device on the substrate is overlapped with an orthographic projection of the pixel drive circuit, to which the light emitting device is electrically connected, on the substrate, and can be more beneficial for the electrical connection between the first electrode of the light emitting device and the corresponding pixel drive circuit.

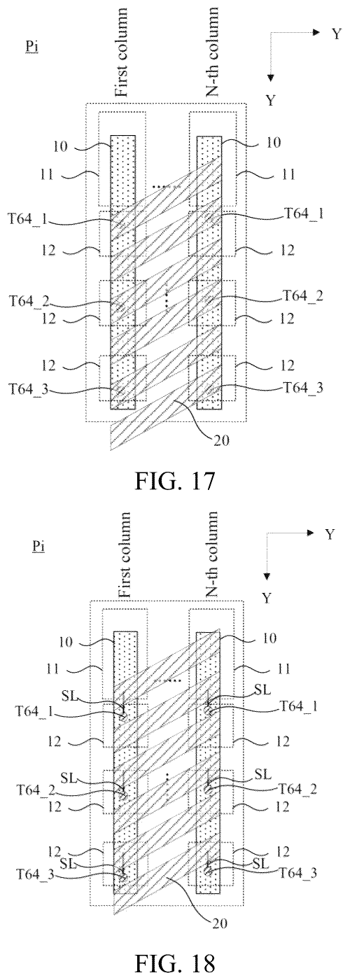

In an exemplary implementation, FIG. 17 is a first schematic diagram of a structure of a pixel island in the display panel provided in FIG. 2B. As shown in FIG. 17, an orthographic projection of a second electrode of a light emitting control transistor of any pixel drive circuit on the substrate is at least partially overlapped with an orthographic projection of a first electrode of a light emitting device, to which the light emitting control transistor is electrically connected, on the substrate, i.e., an orthographic projection of a second electrode T64_k of the k-th light emitting control transistor of the pixel drive circuit at the j-th column on the substrate is at least partially overlapped with an orthographic projection of a first electrode 20 of the k-th light emitting device, to which the pixel drive circuit at the j-th column is electrically connected, on the substrate, i.e., orthographic projections of the second electrodes of the light emitting control transistors of the sub-drive circuit 12 of all the pixel drive circuits within the pixel island on the substrate are at least partially overlapped with orthographic projections of the first electrodes 20 of the light emitting devices, to which the sub-drive circuits 12 are electrically connected, on the substrate. FIG. 17 is illustrated by taking K/N=3 as an example.

In an exemplary implementation, FIG. 18 is a second schematic diagram of a structure of a pixel island in the display panel provided in FIG. 2B. As shown in FIG. 18, an orthographic projection of a second electrode of a light emitting control transistor of any pixel drive circuit on the substrate is not overlapped with an orthographic projection of a first electrode of a light emitting device to which the light emitting control transistor is electrically connected on the substrate, i.e., an orthographic projection of the second electrode T64_k of the k-th light emitting control transistor of the pixel drive circuit at the j-th column on the substrate is not overlapped with an orthographic projection of the first electrode 20 of the k-th light emitting device to which the second electrode T64_k of the k-th light emitting control transistor is electrically connected on the substrate, that is, orthographic projections of the second electrodes of the light emitting control transistors in the sub-drive circuits 12 of all the pixel drive circuits within the pixel island on the substrate are not overlapped with orthographic projections of the first electrodes 20 of the emitting devices to which the sub-drive circuits 12 are electrically connected on the substrate. FIG. 18 is illustrated by taking K/N−3 as an example.

In an exemplary implementation, as shown in FIG. 18, when an orthographic projection of the second electrode of the k-th light emitting control transistor of the pixel drive circuit at the j-th column on the substrate is not overlapped with an orthographic projection of the first electrode of the k-th light emitting device to which the second electrode of the k-th light emitting control transistor is electrically connected on the substrate, at least one pixel island may further include a plurality of signal connection lines SL, wherein the signal connection line SL is electrically connected to the second electrode of the k-th light emitting control transistor of the pixel drive circuit at the j-th column and the first electrode 20 of the k-th light emitting device to which the second electrode of the k-th light emitting control transistor is electrically connected.

In an exemplary implementation, as shown in FIG. 18, the signal connection line SL is arranged in a film layer between a film layer where the second electrode T64_k of the k-th light emitting control transistor of the pixel drive circuit at the j-column is located and a film layer where the first electrode of the k-th light emitting device to which the pixel drive circuit at the j-th column is electrically connected is located.

In an exemplary implementation, the signal connection line SL may be a metal conductive line or a metal oxide conductive line. Exemplarily, a manufacturing material of the metal oxide conductive line may be indium tin oxide or zinc tin oxide, and the metal oxide conductive line is a transparent conductive line.

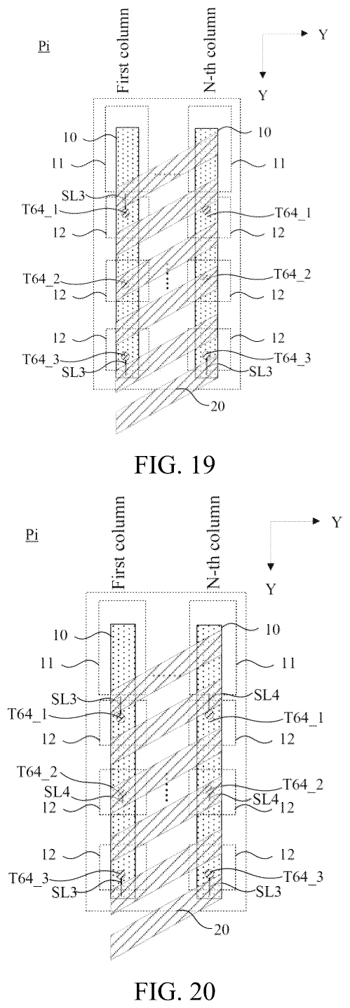

In an exemplary implementation, FIG. 19 is a third schematic diagram of a structure of a pixel island in the display panel provided in FIG. 2B, and FIG. 20 is a fourth schematic diagram of a structure of a pixel island in the display panel provided in FIG. 2B. As shown in FIG. 19 and FIG. 20, the K/N light emitting control transistors in the pixel drive circuit at the j-th column include a first type of transistors and a second type of transistors. An orthographic projection of the second electrode of the first type of transistor on the substrate is not overlapped with an orthographic projection of the first electrode of the light emitting device to which the first type of transistor is electrically connected on the substrate, and an orthographic projection of the second electrode of the second type of transistor on the substrate is at least partially overlapped with an orthographic projection of the first electrode of the light emitting device to which the second type of transistor is electrically connected on the substrate, i.e., orthographic projections of the second electrodes of the light emitting control transistors in the sub-drive circuits 12 of one portion of the pixel drive circuits within the pixel island on the substrate are at least partially overlapped with orthographic projections of the first electrodes 20 of the light emitting devices to which the sub-drive circuits 12 are electrically connected on the substrate, and orthographic projections of the second electrodes of the light emitting control transistors in the sub-drive circuits 12 of the other portion of the pixel circuits within the pixel island on the substrate are not overlapped with orthographic projections of the first electrodes 20 of the light emitting devices to which the sub-drive circuits 12 are electrically connected on the substrate. FIG. 19 and FIG. 20 are illustrated by taking K/N=3 as an example. FIG. 19 and FIG. 20 are illustrated by taking a case where the second light emitting control transistor in the second sub-drive circuit of the pixel drive circuit at the first column is the first-type of transistor, and the first light emitting control transistor in the first sub-drive circuit and the third light emitting control transistor in the third sub-drive circuit of the pixel drive circuit at the first column are the second-type transistors as an example, and a case where the second light emitting control transistor in the second sub-drive circuit of the pixel drive circuit at the N-th column is the first-type of transistor, and the first light emitting control transistor in the first sub-drive circuit and the third light emitting control transistor in the third sub-drive circuit of the pixel drive circuit at the N-th column are the second-type transistor as an example.

In an exemplary implementation, as shown in FIG. 19 and FIG. 20, at least one pixel island further includes a plurality of third signal connection lines SL3, wherein the third signal connection line SL3 is electrically connected to the second electrode of the first type of transistor and the first electrode 20 of the light emitting device to which the first type of transistor is electrically connected.

In an exemplary implementation, the third signal connection line SL3 may be arranged in a film layer between a film layer where the second electrode of the first type of transistor is located and a film layer where the first electrode of the light emitting device to which the first type of transistor is electrically connected is located.

In an exemplary implementation, the third signal connection lines SL3 may be metal conductive lines or metal oxide conductive lines. Exemplarily, a manufacturing material of the metal oxide conductive line may be indium tin oxide or zinc tin oxide, and the metal oxide conductive line is a transparent conductive line.

In an exemplary implementation, as shown in FIG. 20, at least one pixel island may further include a plurality of fourth signal connection lines SL4, wherein the fourth signal connection line SL4 is electrically connected to the second electrode of the second type of transistor and the first electrode of the light emitting device to which the second type of transistor is electrically connected.

In an exemplary implementation, the fourth signal connection lines SL4 may be arranged in the same layer as the third signal connection lines SL.

In an exemplary implementation, the fourth signal connection lines SL4 may be conductive lines or metal oxide conductive lines. Exemplarily, a manufacturing material of the metal oxide conductive line may be indium tin oxide or zinc tin oxide, and the metal oxide conductive line is a transparent conductive line.

In an exemplary implementation, the fourth signal connection line SL4 may serve as a connection electrode between the first electrode of the light emitting device and the sub-drive circuit of the electrically connected pixel drive circuit, which can avoid that a depth of a via exposing the second electrode of the sixth transistor in the sub-drive circuit of the pixel drive circuit is larger when the first electrode of the light emitting device is directly connected with the second electrode of the sixth transistor in the sub-drive circuit of the electrically connected pixel drive circuit, and can improve the reliability of the display panel.

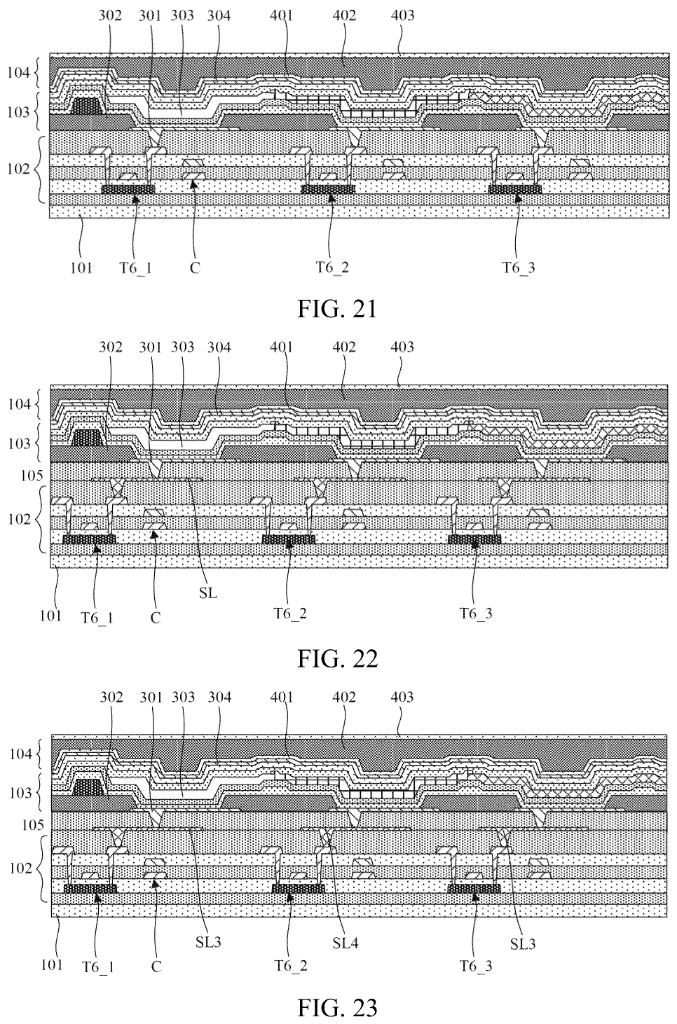

FIG. 21 is a first schematic diagram of a structure of the display panel provided in FIG. 2B. FIG. 22 is a second schematic diagram of a structure of the display panel provided in FIG. 2B. FIG. 23 is a third schematic diagram of a structure of the display panel provided in FIG. 2B. FIG. 21 to FIG. 23 illustrate structures of three sub-pixels within the pixel islands of the display panels. As shown in FIG. 21 to FIG. 23, on a plane perpendicular to the display panel, the display panel may include a drive circuit layer 102 arranged on the substrate 101, a light emitting structure layer 103 arranged on a side of the drive circuit layer 102 away from the substrate 101, and an encapsulation structure layer 104 arranged on a side of the light emitting structure layer 103 away from the substrate 101.

In an exemplary implementation, the display substrate may include another film layer, such as a touch control structure layer, which is not limited in the present disclosure.

In an exemplary implementation, the substrate 101 may be a flexible substrate, or a rigid substrate.

In an exemplary implementation, the drive circuit layer 102 of each sub-pixel may include multiple transistors and a capacitor forming a pixel drive circuit. FIG. 21 to FIG. 23 are illustrated by taking a sixth transistor T6 and one capacitor C as an example. The light emitting structure 103 may include a first electrode 301, a pixel definition layer 302, an organic light emitting layer 303 and a second electrode 304. The first electrode 301 is connected with a second electrode of the sixth transistor T6 through a via, the organic light emitting layer 303 is connected with the first electrode 301, the second electrode 304 is connected with the organic light emitting layer 303, and the organic light emitting layer 303 emits light of a corresponding color under the drive of the first electrode 301 and the second electrode 304.

In an exemplary implementation, a thickness of the pixel definition layer may be 1.5-3 microns, and the material adopted by the pixel definition layer may be, for example, an inorganic material (silicon nitride or silicon oxide, etc.) or an organic material (e.g. polyimide, polytetrafluoroethylene), or may be a photoresist (e.g. polyvinyl alcohol, laurate).

In an exemplary implementation, the encapsulation structure layer 104 may include a first encapsulation layer 401, a second encapsulation layer 402, and a third encapsulation layer 403 that are stacked. The first encapsulation layer 401 and the third encapsulation layer 403 may be made of an inorganic material, and the second encapsulation layer 402 may be made of an organic material. The second encapsulation layer 402 is arranged between the first encapsulation layer 401 and the third encapsulation layer 403, which can ensure that external moisture cannot enter the light emitting structure layer 103. Exemplarily, the first encapsulation layer and the third encapsulation layer may be made of any one or more of the following: Silicon Oxide (SiOx), Silicon Nitride (SiNx), and Silicon Oxynitride (SiON), may be a single layer, a multi-layer, or a composite layer, may adopt Chemical Vapor Deposition (CVD), or Atomic Layer Deposition (ALD), etc., thus can ensure that external water and oxygen cannot enter the emitting structure layer. The second encapsulation layer may be made of a resin, which plays a role of covering various film layers of the display region, so as to improve structural stability and planarization. In this way, the first encapsulation layer, the second encapsulation layer, and the third encapsulation layer that are stacked form the encapsulation structure layer, and the formed laminated structure of an inorganic material/an organic material/an inorganic material can ensure integrity of encapsulation and effectively isolate external water and oxygen.

In an exemplary implementation, the touch structure layer may include a first touch insulation layer arranged on the encapsulation structure layer, a first touch metal layer arranged on the first touch insulation layer, a second touch insulation layer covering the first touch metal layer, a second touch metal layer arranged on the second touch insulation layer, and a touch protection layer covering the second touch metal layer, wherein the first touch metal layer may include a plurality of bridge electrodes, the second touch metal layer may include a plurality of first and second touch electrodes, and the first or second touch electrodes may be connected to the bridge electrodes through vias.

FIG. 21 is illustrated by taking a case where an orthographic projection of the second electrode T64_k of the k-th light emitting control transistor of the pixel drive circuit at the j-th column on the substrate is at least partially overlapped with an orthographic projection of the first electrode 20 of the light emitting device, to which the second electrode T64_k of the k-th light emitting control transistor is electrically connected, on the substrate, and in this case, the second electrode of each light emitting control transistor of the pixel drive circuit 10 at the j-th column is directly electrically connected to the first electrode 20 of the light emitting device to which the second electrode of the light emitting control transistor is electrically connected.

FIG. 22 is illustrated by taking a case where an orthographic projection of the second electrode T64_k of the k-th light emitting control transistor of the pixel drive circuit at the j-th column on the substrate is not overlapped with an orthographic projection of the first electrode 20 of the light emitting device, to which the second electrode T64_k of the k-th light emitting control transistor is electrically connected, on the substrate, and in this case, the display panel may further include a conductive connection layer 105 arranged between the drive circuit layer 102 and the light emitting structure layer 103, wherein the conductive connection layer 105 includes a signal connection line SL.

FIG. 23 is illustrated by taking a case where orthographic projections of the second electrodes of the light emitting control transistors in the sub-drive circuits 12 of one portion of the pixel drive circuits within the pixel island on the substrate are overlapped at least partially with orthographic projections of the first electrodes 20 of the light emitting devices, to which the sub-drive circuits 12 are electrically connected, on the substrate, and orthographic projections of the second electrodes of the light emitting control transistors in the sub-drive circuits 12 of the other portion of the pixel drive circuits on the substrate are not overlapped with orthographic projections of the first electrodes 20 of the light emitting devices, to which the sub-drive circuits 12 are electrically connected, on the substrate. In this case, the display panel may further include a conductive connection layer 105 arranged between the drive circuit layer 102 and the light emitting structure layer 103, wherein the conductive connection layer 105 includes a third signal connection line SL3 and/or a fourth signal connection line SL4.

In an exemplary implementation, the conductive connection layer may be made of a metal material or a transparent conductive material, and the metal material may include any one or more of Argentum (Ag), Copper (Cu), Aluminum (Al), Titanium (Ti), and Molybdenum (Mo), or an alloy material of the above metals, and the transparent conductive material may include Indium Tin Oxide (ITO) or Indium Zinc Oxide (IZO). In an exemplary implementation, the conductive connection layer may have a single-layer structure or a multi-layer composite structure, such as ITO/Al/ITO.

In an exemplary implementation, an insulation layer is provided between the conductive connection layer and the drive circuit layer, and an insulation layer is also provided between the conductive connection layer and the light emitting structure layer.

In an exemplary implementation, the insulation layer may be made of any one or more of silicon oxide (SiOx), silicon nitride (SiNx) and silicon oxynitride (SiON), and may be a single layer, a multi-layer or a composite layer.

An embodiment of the present disclosure further provides a display apparatus including a display panel.

The display panel is the display panel in accordance with any one of the preceding embodiments, and implementation principles and implementation effects thereof are similar, and will not be repeated herein.

In an exemplary implementation, the display apparatus may be a multi-dimensional stereoscopic display apparatus.

In an exemplary implementation, the display apparatus may also include a timing controller, a data driver, a scan driver, a light emitting driver, and a pixel island arranged in an array.

In an exemplary implementation, the timing controller is connected to the data driver, the scan driver, and the light emitting driver, respectively. In an exemplary implementation, the timing controller may provide the data driver with a gray scale value and a control signal which are suitable for a specification of the data driver, provide the scan driver with a clock signal, a scan starting signal, etc., which are suitable for a specification of the scan driver, and provide the light emitting driver with a clock signal, a light emitting stopping signal, etc., which are suitable for a specification of the light emitting driver.

In an exemplary implementation, the data driver is connected to the data signal line. Exemplarily, the data driver may generate data voltages to be provided to the data signal lines using the gray-scale value and the control signal received from the timing controller. For example, the data driver may sample the gray-scale value using the clock signal, and apply a data voltage corresponding to a gray-scale value to a data signal line by taking a row of pixel islands as a unit.

In an exemplary implementation, the scan driver is connected to the scan signal line. Exemplarily, the scan driver may generate scan signals to be provided to the scan signal lines by receiving the clock signal, the scan starting signal, or the like, from the timing controller. For example, the scan driver may sequentially provide scan signals with on-level pulses to scan signal lines. For example, the scan driver may be constructed in a form of a shift register and may generate a scan signal by sequentially transmitting a scan starting signal provided in a form of an on-level pulse to a next stage circuit under control of the clock signal.

In an exemplary implementation, when the display panel is the display panel provided in FIG. 2A, the light emitting driver is connected to the light emitting control signal line. The light emitting driver may generate emission signals to be provided to the light emitting control signal lines by receiving the clock signal, the emission stopping signal, or the like, from the timing controller. For example, the light emitting driver may provide emission signals with off-level pulses to the light emitting signal lines sequentially. For example, the light emitting driver may be constructed in a form of the shift register and generate an emission signal by sequentially transmitting an emission stopping signal provided in the form of an off-level pulse to a next-stage circuit under the control of the clock signal.

When the display panel is the display panel provided in FIG. 2B, the light emitting driver is connected to the light emitting control signal line and the light emitting signal line, respectively. The light emitting driver may generate emission signals to be provided to the light emitting control signal lines and the light emitting signal lines by receiving the clock signal, the emission stopping signal, or the like, from the timing controller. For example, the light emitting driver may provide emission signals with off-level pulses to the light emitting signal lines sequentially. For example, the light emitting driver may be constructed in a form of the shift register, and generate an emission signal by sequentially transmitting an emission stopping signal provided in the form of an off-level pulse to a next-stage circuit under the control of the clock signal.

In an exemplary implementation, the display panel of the present disclosure may be applied to a display apparatus with a pixel drive circuit, such as an OLED, a Quantum dot display (QLED), a Light Emitting Diode display (Micro LED or Mini LED), or a Quantum Dot Light Emitting Diode display (QDLED), which is not limited here in the present disclosure.

An embodiment of the present disclosure further provides a display equipment, including a display apparatus.

In an exemplary implementation, the display equipment may further include a microlens array. The microlens array may include a plurality of microlenses, which may correspond to a plurality of pixel islands in the display apparatus one by one. Herein, the light emitted by the pixel islands enters the human eye after passing through the corresponding microlens, so that the human eye may see the displayed image. In addition, there is a spacing between the pixel islands, and there is also a spacing between the microlenses. External ambient light may enter human eyes from the spacings between the pixel islands and the spacings between the microlenses, so that human eyes may see display images of pixel islands and external objects at the same time, thus achieving an augmented reality display.

In an exemplary implementation, a plurality of pixel islands may emit light with a plurality of different colors, such as red, blue, and green (for ease of description, the pixel islands emitting red light are referred to as “red pixel islands”, the pixel islands emitting green light are referred to as “green pixel islands”, and the pixel islands emitting blue light are referred to as “blue pixel islands” below). In this case, a target image to be displayed may be considered as a superposition of a red component image, a green component image, and a blue component image. When the display apparatus performs display, each red pixel island displays a portion of the red component image, each green pixel island displays a portion of the green component image, and each blue pixel island displays a portion of the blue component image. The images displayed by all the red pixel islands may be spliced to form a red component image, the images displayed by all the green pixel islands may be spliced to form a green component image, and the images displayed by all the blue pixel islands may be spliced to form a blue component image. The red component image, the blue component image and the blue component image are superimposed on the retina of the human eye to form a complete target image.

In an exemplary implementation, a principle of splicing images displayed by different pixel islands is as follows: after a light beam emitted from each point on the pixel island is refracted by the microlens, a parallel light beam is formed and incident to the lens, and then converges on the retina; moreover, for the human eye, when two parallel light beams with a certain width and the same angle enter the human eye, they will converge at the same position on the retina; and the parallel light incident at different angles will converge at different positions on the retina. Therefore, by reasonably controlling the angles of light beams incident on the lens, images displayed by different pixel islands may be spliced on the retina.

In an exemplary implementation, the display equipment may be a wearable device, and may include, for example, VR glasses, VR helmets, AR glasses, AR helmets, MR glasses or MR helmets.

The display apparatus is a display apparatus provided by any one of the previous embodiments, and has similar implementation principle and implementation effects, which will not be repeated here.

The drawings of the embodiments of the present disclosure only involve structures involved in the embodiments of the present disclosure, and other structures may refer to usual designs.

For the sake of clarity, a thickness and size of a layer or a micro structure are enlarged in the accompanying drawings used to describe the embodiments of the present disclosure. It can be understood that when an element such as a layer, film, region or substrate is described as being “on” or “under” another element, this element may be “directly” located “on” or “under” the another element, or there may be an intermediate element.

Although the implementations disclosed in the present disclosure are as above, the described contents are only implementations used for convenience of understanding the present disclosure and are not intended to limit the present disclosure. Any skilled person in the art to which the present invention pertains can make any modifications and alterations in forms and details of implementations without departing from the spirit and scope of the present disclosure. However, the patent protection scope of the present disclosure should be subject to the scope defined by the appended claims.

1. A display panel, comprising a substrate, and pixel islands arranged in an array on the substrate, wherein at least one pixel island comprises a plurality of pixel drive circuits and a plurality of light emitting devices, a light emitting device comprises a first electrode, and at least one pixel drive circuit is electrically connected with a first electrode of at least one light emitting device; and
first electrodes of a plurality of light emitting devices within a same pixel island are arranged along a first direction, and an orthographic projection of a first electrode of at least one light emitting device on the substrate is at least partially overlapped with an orthographic projection of at least two pixel drive circuits on the substrate.

2. The display panel according to claim 1, wherein at least one pixel island comprises K light emitting devices, and the plurality of pixel drive circuits comprised in the at least one pixel island are arranged in an arrangement of M rows and N columns, wherein the first direction is a column direction, a second direction intersecting with the first direction is a row direction, and M, N are positive integers greater than or equal to 1.

3. The display panel according to claim 2, wherein when M>1, a pixel drive circuit at an i-th row and a j-th column is electrically connected with a first electrode of a light emitting device at an (N*(i−1)+j)-th row, wherein i and j are positive integers, 1≤i≤M, 1≤j≤N, and M*N=K.

4. The display panel according to claim 2, wherein when M=1, a pixel drive circuit at a j-th column is electrically connected to a first electrode of a light emitting device at a (1+K*(j−1)/N)-th row to a first electrode of a light emitting device at a (K*j/N)-th row, respectively, wherein j is a positive integer, and 1≤j≤N.

5. The display panel according to claim 2, wherein pixel drive circuits of adjacent columns located in a same row are mirror symmetrical with respect to a virtual straight line extending along the first direction.

6. The display panel according to claim 3, wherein the at least one pixel island further comprises a plurality of light emitting control signal lines, and the pixel drive circuit comprises a drive transistor and a light emitting control transistor; and
a control electrode of the light emitting control transistor is electrically connected to a light emitting control signal line, a first electrode of the light emitting control transistor is electrically connected to the drive transistor, and a second electrode of the light emitting control transistor is electrically connected to a first electrode of a light emitting device to which the pixel drive circuit is electrically connected.

7. The display panel according to claim 6, wherein the at least one pixel island further comprises a plurality of reset signal lines, a plurality of scan signal lines, a plurality of initial signal lines, a plurality of first power supply lines and a plurality of data signal lines, and the pixel drive circuit further comprises a node reset transistor, a compensation transistor, a writing transistor, and a control transistor;
for any pixel drive circuit, a control electrode of a node reset transistor is electrically connected to a reset signal line, a first electrode of the node reset transistor is electrically connected to an initial signal line, and a second electrode of the node reset transistor is electrically connected to a first node; a control electrode of a compensation transistor is electrically connected to a scan signal line, a first electrode of the compensation transistor is electrically connected to the first node, and a second electrode of the compensation transistor is electrically connected to a third node; a control electrode of a drive transistor is electrically connected to the first node, a first electrode of the drive transistor is electrically connected to a second node, and a second electrode of the drive transistor is electrically connected to the third node; a control electrode of the writing transistor is electrically connected to the scan signal line, a first electrode of the writing transistor is electrically connected to a data signal line, and a second electrode of the writing transistor is electrically connected to the second node; a control electrode of a light emitting transistor is electrically connected to a light emitting control signal line, a first electrode of the light emitting transistor is electrically connected to a first power supply line, and a second electrode of the light emitting transistor is electrically connected to the second node; and a first electrode of the sixth transistor is electrically connected to the third node.

8. The display panel according to claim 4, wherein at least one pixel island further comprises K/N light emitting signal lines, and the pixel drive circuit comprises a drive transistor, and K/N light emitting control transistors arranged along the first direction; and
a control electrode of a k-th light emitting control transistor is electrically connected with a k-th light emitting signal line, a first electrode of the k-th light emitting control transistor is electrically connected with the drive transistor, and a second electrode of the k-th light emitting control transistor is electrically connected with a k-th light emitting device to which the pixel drive circuit is electrically connected, wherein k is a positive integer and 1≤k≤K/N.

9. The display panel according to claim 8, wherein at least one pixel island further comprises one reset signal line, one scan signal line, one light emitting control signal line, one initial signal line, at least one first power supply line, and a plurality of data signal lines, and the pixel drive circuit further comprises a node reset transistor, a compensation transistor, a writing transistor, and a control transistor;
for any pixel drive circuit, a control electrode of a node reset transistor is electrically connected to a reset signal line, a first electrode of the node reset transistor is electrically connected to an initial signal line, and a second electrode of the node reset transistor is electrically connected to a first node; a control electrode of a compensation transistor is electrically connected to a scan signal line, a first electrode of the compensation transistor is electrically connected to the first node, and a second electrode of the compensation transistor is electrically connected to a third node; a control electrode of a drive transistor is electrically connected to the first node, a first electrode of the drive transistor is electrically connected to a second node, and a second electrode of the drive transistor is electrically connected to the third node; a control electrode of the writing transistor is electrically connected to the scan signal line, a first electrode of the writing transistor is electrically connected to a data signal line, and a second electrode of the writing transistor is electrically connected to the second node; a control electrode of a light emitting transistor is electrically connected to a light emitting control signal line, a first electrode of the light emitting transistor is electrically connected to a first power supply line, and a second electrode of the light emitting transistor is electrically connected to the second node; and a first electrode of a k-th light emitting control transistor is electrically connected to the third node.

10. The display panel according to claim 9, wherein when a signal of one light emitting signal line is an effective level signal, signals of other light emitting signal lines are all ineffective level signals except the light emitting signal line whose signal is an effective level; and
time for which a signal of any one light emitting signal line is an effective level signal is partially overlapped with time for which a signal of the light emitting control signal line is an effective level signal.

11. The display panel according to claim 6,
wherein an orthographic projection of the second electrode of the light emitting control transistor of any one pixel drive circuit on the substrate is at least partially overlapped with an orthographic projection of the first electrode of the light emitting device, to which the light emitting control transistor is electrically connected, on the substrate;
or
an orthographic projection of the second electrode of the light emitting control transistor of any one pixel drive circuit on the substrate is not overlapped with an orthographic projection of the first electrode of the light emitting device, to which the light emitting control transistor is electrically connected, on the substrate.

12. (canceled)

13. The display panel according to claim 11, wherein at least one pixel island further comprises a plurality of signal connection lines, and a signal connection line is arranged in a film layer between a film layer where the second electrode of the light emitting control transistor is located and a film layer where the first electrode is located;
the signal connection line is electrically connected to the second electrode of the light emitting control transistor of the pixel drive circuit and the first electrode of the light emitting device to which the light emitting control transistor is electrically connected; and
the signal connection line is a metal conductive line or metal oxide conductive line.

14. The display panel according to claim 6, wherein the pixel drive circuit comprises a first pixel drive circuit and a second pixel drive circuit;
an orthographic projection of a second electrode of a light emitting control transistor of the first pixel drive circuit on the substrate is not overlapped with an orthographic projection of a first electrode of a light emitting device, to which the first pixel drive circuit is electrically connected, on the substrate, and an orthographic projection of a second electrode of a light emitting control transistor of the second pixel drive circuit on the substrate is at least partially overlapped with an orthographic projection of a first electrode of a light emitting device, to which a second pixel drive circuit is electrically connected, on the substrate.

15. The display panel according to claim 14, wherein at least one pixel island further comprises a plurality of first signal connection lines, and a first signal connection line is arranged in a film layer between a film layer where the second electrode of the light emitting control transistor is located and a film layer where the first electrode is located;
the first signal connection line is electrically connected with the second electrode of the light emitting control transistor of the first pixel drive circuit and the first electrode of the light emitting device to which the first pixel drive circuit is electrically connected; and
the first signal connection line is a metal conductive line or metal oxide conductive line.

16. The display panel according to claim 15, wherein at least one pixel island further comprises a plurality of second signal connection lines, and a second signal connection line is arranged in a same layer as the first signal connection line;
the second signal connection line is electrically connected to the second electrode of the light emitting control transistor of the second pixel drive circuit and the first electrode of the light emitting device to which the second pixel drive circuit is electrically connected; and
the second signal connection line is a metal conductive line or metal oxide conductive line.

17. The display panel according to claim 8, wherein the K/N light emitting control transistors of the pixel drive circuit comprise a first type of transistors and a second type of transistors, wherein an orthographic projection of a second electrode of a first type of transistor on the substrate is not overlapped with an orthographic projection of a first electrode of a light emitting device to which the first type of transistor is electrically connected on the substrate, and an orthographic projection of a second electrode of a second type of transistor on the substrate is at least partially overlapped with an orthographic projection of a first electrode of a light emitting device to which the second type of transistor are electrically connected on the substrate.

18. The display panel according to claim 17, wherein at least one pixel island further comprises a plurality of third signal connection lines, and a third signal connection line is arranged in a film layer between a film layer where a second electrode of a first type of transistor is located and a film layer where a first electrode is located;
the third signal connection line is electrically connected to the second electrode of the first type of transistor and the first electrode of the light emitting device to which the first type of transistor is electrically connected; and
the third signal connection line is a metal conductive line or metal oxide conductive line.

19. The display panel according to claim 18, wherein at least one pixel island further comprises a plurality of fourth signal connection lines, and a fourth signal connection line is arranged in a same layer as the third signal connection line;
the fourth signal connection line is electrically connected to a second electrode of a second type of transistor and a first electrode of a light emitting device to which a second type of transistors is electrically connected; and
the fourth signal connection line is a metal conductive line or metal oxide conductive line.

20. The display panel according to claim 1, wherein the pixel island comprises a first color pixel island, a second color pixel island and a third color pixel island, and adjacent first color pixel island, second color pixel island and third color pixel island, that are three adjacent pixel islands, form one pixel; and
a first color pixel island, a second color pixel island and a third color pixel island located within a same pixel are arranged along a second direction, wherein the first direction intersects with the second direction;
or
a shape of the first electrode of the light emitting device is a parallelogram; and an extension direction of short sides of the parallelogram is parallel to the first direction.

21. (canceled)

22. A display apparatus, comprising: the display panel of claim 1.
